(19) United States
(12) Patent Application Publication
(10) Pub. No.: US 2025/0204215 A1
(43) Pub. Date: Jun. 19, 2025

(54) DISPLAY DEVICE

(71) Applicant: Samsung Display Co., LTD., Yongin-si (KR)

(72) Inventor: Ki Ho BANG, Yongin-si (KR)

(21) Appl. No.: 18/765,223

(22) Filed: Jul. 6, 2024

(30) Foreign Application Priority Data
Dec. 15, 2023 (KR) 10-2023-0182523

(51) Int. Cl. H10K 59/80; H10K 59/124; H10K 59/40

(52) U.S. Cl. CPC H10K 59/873; H10K 59/124; H10K 59/40

(57) ABSTRACT

A display device includes a display panel. The display panel includes a circuit layer disposed on a substrate; and an element layer disposed on the circuit layer. A main area of the substrate includes a display area including emission areas, and a non-display area. The display area includes a front display area and a peripheral display area disposed around the front display area and having a curved shape. The element layer includes light emitting elements respectively disposed in the emission areas. The circuit layer includes emission pixel drivers electrically connected to the light emitting elements, respectively, and an alignment mark disposed in the non-display area. An edge of the main area includes four corner points where sides of the main area extending in different directions are connected to each other. The alignment mark is disposed adjacent to a corner point of the four corner points.

This application claims priority to Korean Patent Application No. 10-2023-0182523, filed on Dec. 15, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

The display devices may be flat panel display devices such as liquid crystal display devices, field emission display devices, or light emitting display devices. Here, the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device may display an image using light emitting elements each including a light emitting layer made of an organic light emitting material. As such, the organic light emitting display device implements image display using self-light emitting elements, and accordingly, may have various desired characteristic such as low power consumption, high response speed, high luminous efficiency, high luminance, and wide viewing angle, or the like.

A display surface of the display device from which light is emitted may include a display area where an image is displayed and a non-display area, which is a peripheral area of the display area. Emission areas for emitting light of each luminance and color may be arranged in the display area.

### SUMMARY

When the display area of the display surface of the display device is disposed to be wider, an area of the display device where the light is emitted becomes wider, such that aesthetic appeal may be improved and compatibility with various electronic devices may be improved. Accordingly, methods for reducing a width of the non-display area of the display surface have been researched and developed.

However, there are lines and elements to be disposed in the non-display area, and thus, there is a limitation in reducing the width of the non-display area.

Embodiments of the disclosure provide a display device in which a width of a non-display area viewed in a front direction facing a display surface may be reduced by transforming an edge of a display area into a curved shape.

However, embodiments of the disclosure are not restricted to those set forth herein. The above and other features of embodiments of the disclosure will become more apparent to one of ordinary skill in the art to which the disclosure pertains by referencing the detailed description of embodiments of the disclosure given below.

According to an embodiment of the disclosure, a display device includes a display panel which emits light to display an image. In such an embodiment, the display panel includes a substrate; a circuit layer disposed on the substrate; and an element layer disposed on the circuit layer. In such an embodiment, a main area of the substrate includes a display area where emission areas are arranged and a non-display area disposed around the display area, the display area includes a front display area and a peripheral display area disposed around the front display area and having a curved shape, and the element layer includes light emitting elements respectively disposed in the emission areas. In such an embodiment, the circuit layer includes emission pixel drivers electrically connected to the light emitting elements, respectively; and an alignment mark disposed in the non-display area. In such an embodiment, an edge of the main area includes four corner points where sides of the main area extending in different directions are connected to each other, and the alignment mark is disposed adjacent to a corner point of the four corner points.

In an embodiment, the front display area may include a first side and a second side which extend in a first direction and oppose each other, and a third side and a fourth side which extend in a second direction crossing the first direction and oppose each other. In such an embodiment, the peripheral display area may include a first side area, a second side area, a third side area, and a fourth side area in contact with the first side, the second side, the third side, and the fourth side of the front display area, respectively; a first corner area in contact with a vertex where the first side and the third side are connected to each other and disposed between the first side area and the third side area; a second corner area in contact with a vertex where the second side and the third side are connected to each other and disposed between the second side area and the third side area; a third corner area in contact with a vertex where the second side and the fourth side are connected to each other and disposed between the second side area and the fourth side area; and a fourth corner area in contact with a vertex where the first side and the fourth side are connected to each other and disposed between the first side area and the fourth side area. In such an embodiment, the alignment mark may include at least one selected from: a first alignment mark disposed adjacent to the first corner area; a second alignment mark disposed adjacent to the second corner area; a third alignment mark disposed adjacent to the third corner area; and a fourth alignment mark disposed adjacent to the fourth corner area.

In an embodiment, the display panel may further include a sealing layer disposed on the element layer; a touch sensor layer disposed on the sealing layer; and one or more dam portions arranged in a dam area of the non-display area surrounding the display area and spaced apart from the display area. In such an embodiment, the circuit layer may include an interlayer insulating layer disposed on the substrate; a first source/drain conductive layer disposed on the interlayer insulating layer; a first planarization layer covering the first source/drain conductive layer; a second source/drain conductive layer disposed on the first planarization layer; and a second planarization layer covering the second source/drain conductive layer. In such an embodiment, the element layer may include a pixel defining layer disposed on the circuit layer and overlapping an area between the emission areas spaced apart from each other; and a spacer layer disposed on portions of the pixel defining layer. In such an embodiment, the touch sensor layer may include a touch buffer layer disposed on the sealing layer; a first touch conductive layer disposed on the touch buffer layer; a touch interlayer insulating layer covering the first touch conductive layer; a second touch conductive layer disposed on the touch interlayer insulating layer; and a touch planarization layer covering the second touch conductive layer. In such an embodiment, the one or more dam portions may include two or more dam layers, and each of the two or more dam layers may be disposed at the same layer as a corresponding one of the first planarization layer, the second planarization layer, the pixel defining layer, and the spacer layer.

In an embodiment, the touch interlayer insulating layer may include an organic insulating material, and the display device may further include capping portions disposed at the first touch conductive layer, overlapping the dam area, and spaced apart from the alignment marks.

In an embodiment, the display device may further include capping connection portions connect neighboring capping portions of the capping portions to each other, disposed to have a smaller width than the capping portions, and spaced apart from the alignment marks in a plan view.

In an embodiment, the circuit layer may further include a power supply line disposed in the non-display area, where the power supply line transfers a power for driving the light emitting elements. In such an embodiment, a portion of the power supply line overlapping the dam area includes a first line layer disposed at a same layer as the first source/drain conductive layer and a second line layer disposed at a same layer as the second source/drain conductive layer and in contact with the first line layer, and each of the alignment marks may be defined by an engraved pattern defined through the first line layer and the second line layer which are sequentially stacked.

In an embodiment, the circuit layer may further include a first semiconductor layer disposed on the substrate; a first gate insulating layer covering the first semiconductor layer; a first gate conductive layer disposed on the first gate insulating layer; a second gate insulating layer covering the first gate conductive layer; and a second gate conductive layer disposed on the second gate insulating layer.

In an embodiment, the interlayer insulating layer may cover the second gate conductive layer, and the alignment mark may be defined by an embossed pattern disposed at a same layer as one of the first gate conductive layer and the second gate conductive layer.

In an embodiment, the circuit layer may further include an auxiliary interlayer insulating layer covering the second gate conductive layer; a second semiconductor layer disposed on the auxiliary interlayer insulating layer; a third gate insulating layer covering the second semiconductor layer; and a third gate conductive layer disposed on the third gate insulating layer and covered with the interlayer insulating layer. In such an embodiment, the alignment mark may be defined by an embossed pattern disposed at a same layer as one of the first gate conductive layer, the second gate conductive layer, and the third gate conductive layer.

In an embodiment, the display device may further include a bracket supporting the display panel; and a cover window disposed on the display panel and coupled to the bracket.

In such an embodiment, the cover window may be provided with an alignment hole defined therein to correspond to the alignment marks, and the peripheral display area has a shape curved toward the bracket.

In an embodiment, the alignment mark may include two or more keys spaced apart from each other.

According to an embodiment of the disclosure, there is provided a display device comprises a display panel which emits light to display an image; a bracket supporting the display panel; and a cover window disposed on the display panel and coupled to the bracket. In such an embodiment, the display panel includes a substrate; a circuit layer disposed on the substrate; and an element layer disposed on the circuit layer. In such an embodiment, a main area of the substrate includes a display area where emission areas are arranged and a non-display area disposed around the display area, the display area includes a front display area and a peripheral display area disposed around the front display area and having a shape curved toward the bracket, and the circuit layer includes an alignment mark disposed in the non-display area. In such an embodiment, an edge of the main area includes four corner points where sides of the main area extending in different directions are connected to each other. In such an embodiment, the alignment mark is disposed adjacent to a corner point of the four corner points, and the cover window is provided with an alignment hole defined therein to correspond to the alignment marks.

In an embodiment, the element layer may include light emitting elements respectively disposed in the emission areas, and the circuit layer may further include emission pixel drivers electrically connected to the light emitting elements, respectively; and a power supply line disposed in the non-display area, where the power supply line transfers a power for driving the light emitting elements.

In an embodiment, the display panel may further include a scaling layer disposed on the element layer; a touch sensor layer disposed on the scaling layer; and one or more dam portions arranged in a dam area of the non-display area surrounding the display area and spaced apart from the display area. In such an embodiment, the circuit layer may include a first semiconductor layer disposed on the substrate; a first gate insulating layer covering the first semiconductor layer; a first gate conductive layer disposed on the first gate insulating layer; a second gate insulating layer covering the first gate conductive layer; and a second gate conductive layer disposed on the second gate insulating layer; an interlayer insulating layer disposed on the second gate conductive layer; a first source/drain conductive layer disposed on the interlayer insulating layer; a first planarization layer covering the first source/drain conductive layer; a second source/drain conductive layer disposed on the first planarization layer; and a second planarization layer covering the second source/drain conductive layer. In such an embodiment, the element layer may include a pixel defining layer disposed on the circuit layer and overlapping an area between the emission areas spaced apart from each other; and a spacer layer disposed on portions of the pixel defining layer. In such an embodiment, the touch sensor layer may include a touch buffer layer disposed on the sealing layer; a first touch conductive layer disposed on the touch buffer layer; a touch interlayer insulating layer covering the first touch conductive layer; a second touch conductive layer disposed on the touch interlayer insulating layer; and a touch planarization layer covering the second touch conductive layer. In such an embodiment, the one or more dam portions include two or more dam layers, and each of the two or more dam layers is disposed at the same layer as a corresponding one of the first planarization layer, the second planarization layer, the pixel defining layer, and the spacer layer.

In an embodiment, the touch interlayer insulating layer may include an organic insulating material, and the display device may further include capping portions disposed at the first touch conductive layer, overlapping the dam area, and spaced apart from the alignment mark in a plan view.

In an embodiment, the display device may further include capping connection portions connect neighboring capping portions of the capping portions to each other, disposed to have a smaller width than the capping portions, and spaced apart from the alignment marks.

In an embodiment, a portion of the power supply line overlapping the dam area includes a first line layer disposed at a same layer as the first source/drain conductive layer and a second line layer disposed at a same layer as the second source/drain conductive layer and in contact with the first line layer. In such an embodiment, the alignment mark may be defined by an engraved pattern defined through the first line layer and the second line layer which are sequentially stacked.

In an embodiment, the interlayer insulating layer covers the second gate conductive layer, and the alignment marks may be defined by an embossed pattern disposed in a same layer as one of the first gate conductive layer and the second gate conductive layer.

In an embodiment, the circuit layer may further include an auxiliary interlayer insulating layer covering the second gate conductive layer; a second semiconductor layer disposed on the auxiliary interlayer insulating layer; a third gate insulating layer covering the second semiconductor layer; and a third gate conductive layer disposed on the third gate insulating layer and covered with the interlayer insulating layer. In such an embodiment, the alignment mark may be defined by an embossed pattern disposed in a same layer as one of the first gate conductive layer, the second gate conductive layer, and the third gate conductive layer.

In an embodiment, the alignment mark may include two or more keys having different shapes from each other and spaced apart from each other in a plan view.

A display device according to embodiments may include a display panel which emits light to display an image, and a main area of a substrate of the display panel may include a display area where emission areas are arranged and a non-display area disposed around the display area. In such embodiments, the display area may include a front display area and a peripheral display area disposed around the front display area and having a curved shape.

According to embodiments, the peripheral display area may include a first side area, a second side area, a third side area, and a fourth side area in contact with a first side, a second side, a third side, and a fourth side of the front display area, respectively, and a first corner area, a second corner area, a third corner area, and a fourth corner area in contact with vertices where any two of the first side, the second side, the third side, and the fourth side of the front display area are connected to each other, respectively.

In such embodiments, as described above, the display area includes the peripheral display area having the curved shape, and accordingly, the non-display area connected to the peripheral display area may have a curved shape along with the peripheral display area. That is, a width of the non-display area having the curved shape, viewed in a front direction facing a display surface may be smaller than a width of the non-display area in a non-curved state. Accordingly, a width of the display area of the display surface of the display device viewed in the front direction may increase, and thus, aesthetic appeal and compatibility of the display device may be improved.

According to embodiments, a circuit layer of the display panel may include four alignment marks disposed in the non-display area and respectively adjacent to the four points of an edge of the main area where sides of the main area extending in different directions are connected to each other.

That is, according to embodiments, the four alignment marks respectively adjacent to four corner points of the main area are disposed in the non-display area.

In such embodiments, the edge of the main area of the display panel may be more precisely inferred by the four alignment marks even in a state in which the non-display area is transformed into the curved shape along with the peripheral display area, and thus, a process effort during an alignment process between the display panel and a cover window may be reduced.

### BRIEF DESCRIPTION OF THE DRAWINGS

The above and other features of embodiments of the disclosure will become more apparent by describing in detail embodiments thereof with reference to the attached drawings, in which:

FIG. 1 is a perspective view illustrating a display device according to embodiments;

FIG. 2 is a cross-sectional view taken along line A-A′ of FIG. 1;

FIG. 3 is a plan view illustrating a display panel of FIG. 2;

FIG. 4 is a layout diagram illustrating portion C of FIG. 3;

FIG. 5 is a plan view illustrating a cover window of FIG. 2;

FIG. 6 is a view illustrating an alignment process between the display panel and the cover window according to embodiments;

FIG. 7 is a cross-sectional view of the display panel taken along line B-B′ of FIG. 1;

FIG. 8 is a schematic plan view illustrating a touch sensor layer of FIG. 7 according to embodiments;

FIG. 9 is an enlarged plan view illustrating portion E of FIG. 8;

FIG. 10 is an equivalent circuit diagram illustrating an emission pixel driver of FIG. 4 according to an embodiment;

FIG. 11 is a cross-sectional view taken along line F-F′ of FIG. 9 according to an embodiment of FIG. 10;

FIG. 12 is an equivalent circuit diagram illustrating an emission pixel driver of FIG. 4 according to an embodiment;

FIG. 13 is a cross-sectional view taken along line F-F′ of FIG. 9 according to an embodiment of FIG. 12;

FIG. 14 is a plan view illustrating portion D of FIG. 3 according to an embodiment;

FIG. 15 is a cross-sectional view taken along line G-G′ of FIG. 14;

FIG. 16 is a cross-sectional view taken along line H-H′ of FIG. 14;

FIG. 17 is a plan view illustrating portion D of FIG. 3 according to an embodiment;

FIG. 18 is a plan view illustrating portion D of FIG. 3 according to an embodiment;

FIG. 19 is a cross-sectional view taken along line I-I′ of FIG. 18;

FIG. 20 is a plan view illustrating portion D of FIG. 3 according to an embodiment; and

FIG. 21 is a cross-sectional view taken along line J-J′ of FIG. 20.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on” another element or layer, the element or layer can be directly on another element or layer or intervening elements or layers. In contrast, when an element is referred to as being “directly on” another element, there are no intervening elements present. Like reference numerals refer to like elements throughout the specification. Shapes, sizes, ratios, angles, numbers, etc. disclosed in the drawings for describing embodiments are merely an example, and the disclosure is not limited to the illustrated details.

It will be understood that, although the terms first, second, third, etc., may be used herein to describe various elements, these elements should not be limited by these terms. These terms are only used to distinguish one element from another element. Thus, a first element discussed below could be termed a second element without departing from the teachings of the disclosure.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of various embodiments of the disclosure may be partially or entirely coupled to or combined with each other, and may be inter-operated and driven in technically various ways. The embodiments may be implemented independently from each other, or may be implemented together in a co-dependent relationship.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described in detail with reference to the accompanying drawings.

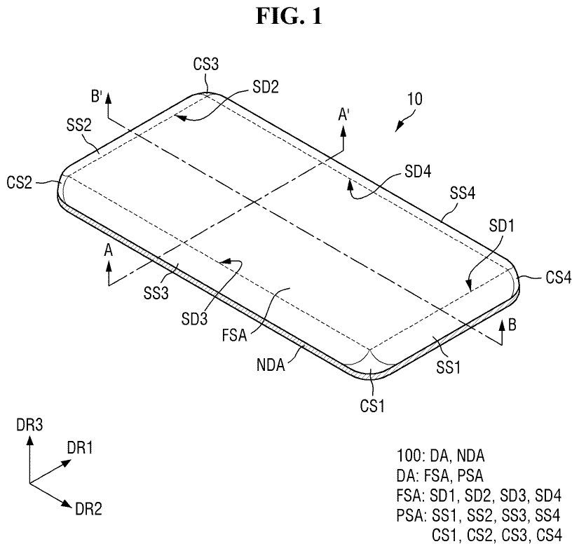

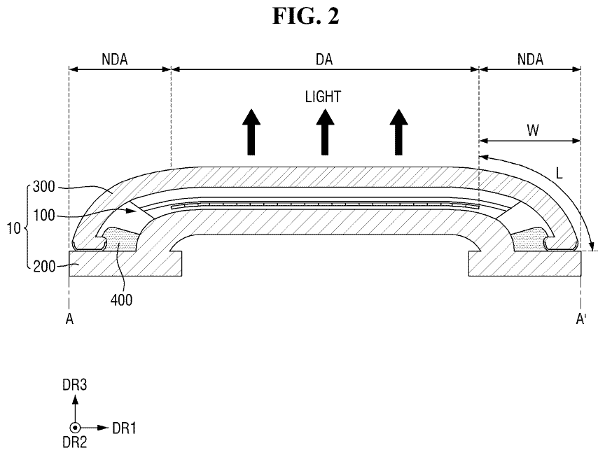

FIG. 1 is a perspective view illustrating a display device according to embodiments. FIG. 2 is a cross-sectional view taken along line A-A′ of FIG. 1.

Referring to FIG. 1, a display device 10 according to embodiments is a device that displays a moving image or a still image, and may be used to provide a display screen of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

Alternatively, the display device 10 according to embodiments may be applied to a center information display (CID) disposed on an instrument board, a center fascia, or a dashboard of a vehicle, a room mirror display substituting for a side-view mirror of the vehicle, or a display disposed on a rear surface of a front seat as entertainment for a rear seat of the vehicle.

Referring to FIG. 2, the display device 10 according to embodiments may include a display panel 100 emitting light for displaying an image.

In addition, the display device 10 according to embodiments may further include a bracket 200 supporting the display panel 100 and a cover window 300 disposed on the display panel 100 and coupled to the bracket 200.

The display panel 100 may be a light emitting display panel including light emitting elements. In an embodiment, for example, the display panel 100 may be an organic light emitting display panel using organic light emitting diodes including organic light emitting layers, a micro light emitting diode display panel using micro light emitting diodes (LEDs), a quantum dot light emitting display panel using quantum dot light emitting diodes including quantum dot light emitting layers, or an inorganic light emitting display panel using inorganic light emitting elements including inorganic semiconductors. Hereinafter, for convenience of description, embodiments where the display panel 100 is an organic light emitting display panel will be mainly described.

The bracket 200 may include a rigid insulating material to prevent deformation of the display panel 100 and alleviate external physical and electrical shocks to the display panel 100. However, this is only an example, and a material of the bracket 200 may be variously changed.

The cover window 300 may include a light transmitting material. The cover window 300 may include or be made of an inorganic material such as glass or an organic material such as plastic or a polymer material.

The cover window 300 may be coupled (e.g., fastened) to the bracket 200 through an adhesive material 400 disposed at an edge thereof.

The cover window 300 may also be attached onto the display panel 100 by a transparent adhesive member such as an optically clear adhesive (OCA) film or an optically clear resin (OCR).

In such an embodiment, the cover window 300 may protect the display panel 100 from electrical and physical shocks on a display surface.

As illustrated in FIG. 1, according to embodiments, the display panel 100 may include a display area DA where light is emitted and a non-display area NDA disposed around the display area DA.

The display area DA may include a front display area FSA having a flat shape and a peripheral display area PSA disposed around the front display area FSA and having a curved shape.

The front display area FSA may include a first side SD1 and a second side SD2 that extend in a first direction DR1 and oppose each other in a second direction DR2 and a third side SD3 and a fourth side SD4 that extend in the second direction DR2, connect the first side SD1 and the second side SD2 to each other, and oppose each other in the first direction DR1.

In an embodiment, for example, the first side SD1 and the second side SD2 may be shorter than the third side SD3 and the fourth side SD4. That is, the front display area FSA may have a quadrangular shape in a plan view (or when viewed in a third direction DR3). Here, the third direction may be a direction perpendicular to a plane defined by the first direction DR1 and the second direction DR2. The third direction DR3 may be a thickness direction of the display device 10.

In another embodiment, for example, corners where each of the first side SD1 and the second side SD2 and each of the third side SD3 and the fourth side SD4 meet together may be formed as arcs having a curved shape or vertices having a right-angled shape.

However, a shape of the front display area FSA according to embodiments is not limited to the quadrangular shape illustrated in FIG. 1, and may also be a polygonal shape other than the quadrangular shape, a circular shape, or an elliptical shape.

The peripheral display area PSA may include a first side area SS1 in contact with the first side SD1 of the front display area FSA, a second side area SS2 in contact with the second side SD2 of the front display area FSA, a third side area SS3 in contact with the third side SD3 of the front display area FSA, and a fourth side area SS4 in contact with the fourth side SD4 of the front display area FSA.

In addition, the peripheral display area PSA may further include a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

The first side area SS1 may extend from the first side SD1 and be curved with a predetermined first curvature toward the bracket 200.

The second side area SS2 may extend from the second side SD2 and be curved with a predetermined second curvature toward the bracket 200. The second curvature may be in a range that is the same as that of the first curvature.

The third side area SS3 may extend from the third side SD3 and be curved with a predetermined third curvature toward the bracket 200. The third curvature may be in a range that is the same as or similar to that of the first curvature or the second curvature, but is not limited thereto.

The fourth side area SS4 may extend from the fourth side SD4 and be curved with a predetermined fourth curvature toward the bracket 200. The fourth curvature may be in a range that is the same as that of the third curvature.

The first corner area CS1 may be disposed between one side of the first side area SS1 and one side of the third side area SS3.

The first corner area CS1 may be a double-curvature area curved with the first curvature of the first side area SS1 and the third curvature of the third side area SS3.

The second corner area CS2 may be disposed between one side of the second side area SS2 and other side of the third side area SS3.

The second corner area CS2 may be a double-curvature area curved with the second curvature of the second side area SS2 and the third curvature of the third side area SS3.

The third corner area CS3 may be disposed between other side of the second side area SS2 and one side of the fourth side area SS4.

The third corner area CS3 may be a double-curvature area curved with the second curvature of the second side area SS2 and the fourth curvature of the fourth side area SS4.

The fourth corner area CS4 may be disposed between other side of the first side area SS1 and other side of the fourth side area SS4.

The fourth corner area CS4 may be a double-curvature area curved with the first curvature of the first side area SS1 and the fourth curvature of the fourth side area SS4.

As described above, according to embodiments, the display area DA includes not only the front display area FSA having the flat shape, but also the peripheral display area PSA having the shape curved toward the bracket 200.

The non-display area NDA is disposed around the display area DA, and may thus be connected to an outer side of the peripheral display area PSA.

That is, the non-display area NDA connected to the peripheral display area PSA having the curved shape may have a curved shape along with the peripheral display area PSA having the curved shape.

As illustrated in FIG. 2, the display device 10 may include a display area DA where light of the display panel 100 is emitted and a non-display area NDA which is disposed around the display area DA and where the light is not emitted.

The display area DA of the display panel 100 may have a shape in which the peripheral display area PSA (see FIG. 1) of an edge thereof is curved toward the bracket 200. Accordingly, the non-display area NDA of the display device 10 may be disposed on side surfaces of the display device 10 due to the peripheral display area PSA having the curved shape.

In addition, each of the bracket 200 and the cover window 300 may have a shape in which an edge thereof is curved to correspond to (or as similar to) the display panel 100.

Accordingly, a width W of the non-display area NDA having the curved shape in the display device 10, when viewed in a front direction (e.g., an opposite direction to the third direction DR3) facing light LIGHT of the front display area FSA (see FIG. 1) of the display device 10 may be smaller than a width L of the non-display area NDA in a non-curved state.

Therefore, as the width W of the non-display area NDA viewed in the front direction in a display surface of the display device 10 decreases, a ratio of the display area DA of the display surface may increase, and thus, aesthetic appeal and compatibility of the display device 10 may be improved.

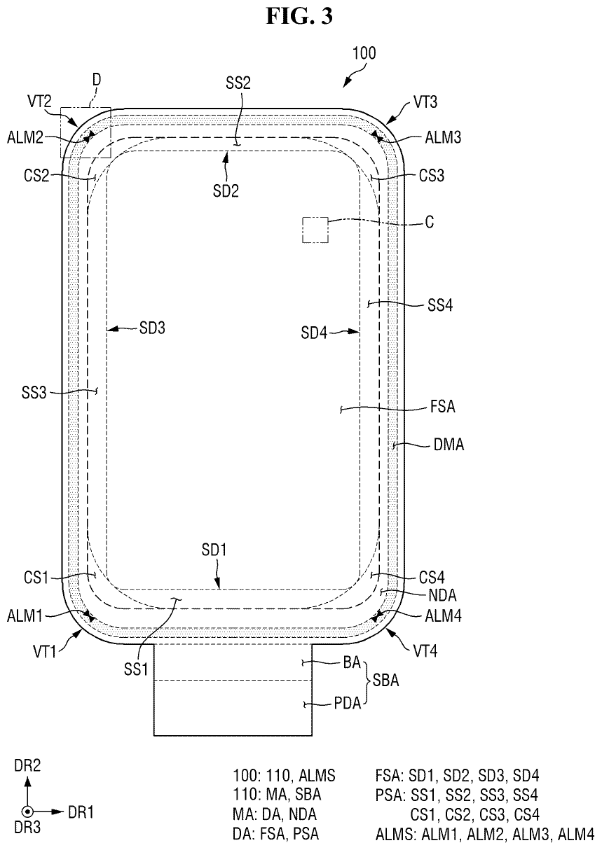

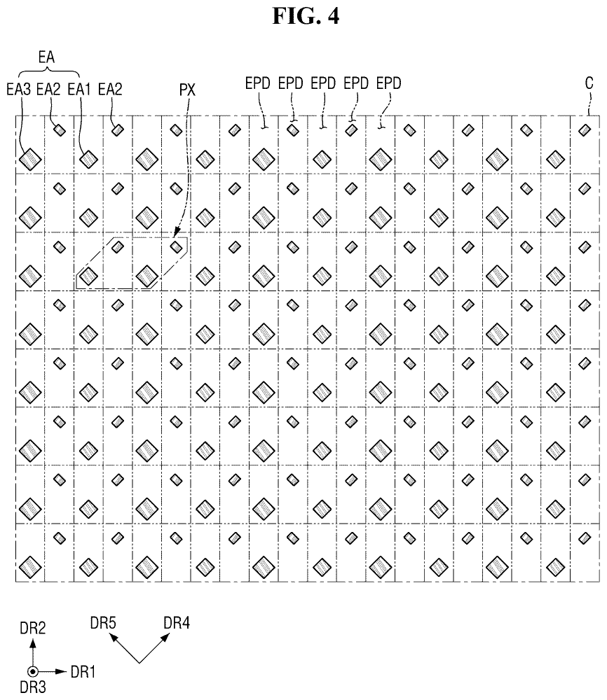

FIG. 3 is a plan view illustrating a display panel of FIG. 2. FIG. 4 is a layout diagram illustrating portion C of FIG. 3.

Referring to FIG. 3, the display panel 100 of the display device 10 according to embodiments may include a substrate 110 and four alignment marks ALMS respectively adjacent to four points VT1, VT2, VT3, and VT4 of an edge of a main area MA of the substrate 110.

The substrate 110 may include the main area MA corresponding to the display surface, and a sub-area SBA protruding from one side of the main area MA.

The main area MA may include a display area DA where light is emitted and a non-display area NDA which is disposed around the display area DA and where the light is not emitted.

Referring to FIG. 4, emission areas EA for emitting light of each color and luminance to display an image may be arranged in the display area DA.

The display area DA may further include a non-emission area disposed in a spaced portion between the emission areas EA.

The emission areas EA may have a rhombic shape in a plan view (or when viewed in the third direction DR3) or a rectangular shape in the plan view. However, this is only an example, and a shape of the emission areas EA in the plan view according to an embodiment is not limited to that illustrated in FIG. 4. Alternatively, the emission areas EA may have a polygonal shape such as a quadrangular shape, a pentagonal shape, or a hexagonal shape in the plan view or have a circular shape or an elliptical shape, in the plan view, including a curved edge.

The emission areas EA may include first emission areas EA1 that emits light of a first color in a predetermined wavelength band, second emission areas EA2 that emits light of a second color in a wavelength band lower than that of the first color, and third emission areas EA3 that emits light of a third color in a wavelength band lower than that of the second color.

In an embodiment, for example, the first color may be red corresponding to a wavelength band of about 600 nanometers (nm) to about 750 nm. The second color may be green corresponding to a wavelength band of about 480 nm to about 560 nm. The third color may be blue corresponding to a wavelength band of about 370 nm to about 460 nm.

The first emission areas EA1 and the third emission areas EA3 may be alternately arranged in at least one of the first direction DR1 and the second direction DR2.

The second emission areas EA2 may be arranged side by side in at least one of the first direction DR1 and the second direction DR2.

In addition, the second emission areas EA2 may neighbor to the first emission areas EA1 and the third emission areas EA3 in diagonal directions DR4 and DR5 crossing the first direction DR1 and the second direction DR2.

Pixels PX displaying each luminance and color may be provided by the first emission areas EA1, the second emission areas EA2, and the third emission areas EA3 adjacent to each other among such emission areas EA.

In other words, the pixels PX may be basic units for displaying various colors including white at a predetermined luminance.

Each of the pixels PX may include at least one first emission area EA1, at least one second emission area EA2, and at least one third emission area EA3 adjacent to each other. Accordingly, each of the pixels PX may display various colors through mixing of light emitted from the first emission area EA1, the second emission area EA2, and the third emission area EA3 adjacent to each other.

As illustrated in FIG. 3, the display area DA of the substrate 110 of the display panel 100 according to embodiments may include a front display area FSA disposed at a center of the main area MA and a peripheral display area PSA disposed around the front display area FSA.

The front display area FSA may maintain a flat shape on a plane defined by the first direction DR1 and the second direction DR2.

The front display area FSA may include a first side SD1 and a second side SD2 that extend in the first direction DR1 and oppose each other in the second direction DR2, and a third side SD3 and a fourth side SD4 that extend in the second direction DR2, connect the first side SD1 and the second side SD2 to each other in the first direction DR1, and oppose each other.

The peripheral display area PSA may be disposed between the front display area FSA and the non-display area NDA. The peripheral display area PSA may have a ring shape surrounding the front display area FSA.

In an embodiment, as illustrated in FIGS. 1 and 2, the peripheral display area PSA may be transformed into a curved shape.

As illustrated in FIG. 3, the peripheral display area PSA may include a first side area SS1, a second side area SS2, a third side area SS3, and a fourth side area SS4 in contact with the first side SD1, the second side SD2, the third side SD3, and the fourth side SD4 of the front display area FSA, respectively, a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

The non-display area NDA may be disposed at (or along) an edge of the main area MA, and may have a ring shape surrounding the display area DA.

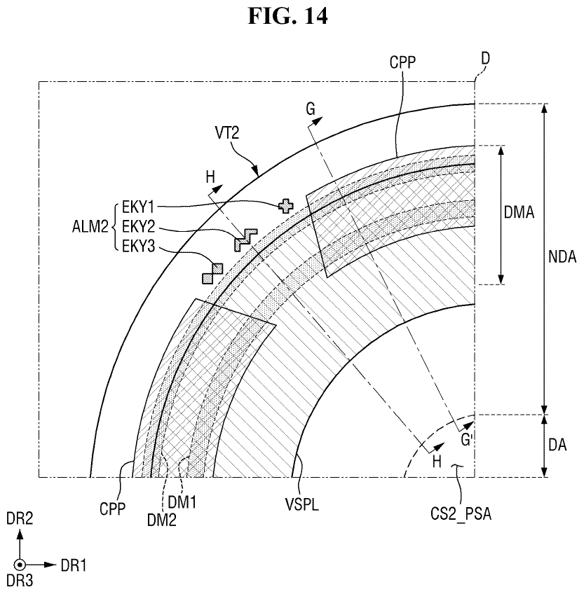

The non-display area NDA may include a dam area DMA surrounding the display area DA and spaced apart from the display area DA. One or more dam portions DM1 and DM2 (see FIGS. 14, 15, and 16) having a ring shape surrounding the display area DA may be arranged in the dam area DMA.

The sub-area SBA may face the first side SD1 of the front display area FSA.

The sub-area SBA may include a bending area BA transformed (or curved) into a bent shape, and a pad area PDA connected to the bending area BA.

When the main area MA has a shape similar to that of the front display area FSA, the edge of the main area MA may include four points VT1, VT2, VT3, and VT4 where sides of the main area MA extending in different directions are connected to each other.

According to embodiments, the display panel 100 may include four alignment marks ALMS disposed in the non-display area NDA and respectively adjacent to the four points VT1, VT2, VT3, and VT4 of the edge of the main area MA in each of which two sides of the main area MA extending in the different directions are connected to each other.

According to embodiments, the alignment marks ALMS may include a first alignment mark ALM1 disposed adjacent to a first corner point VT1 of the main area MA and the first corner area CS1 of the peripheral display area PSA, a second alignment mark ALM2 disposed adjacent to a second corner point VT2 of the main area MA and the second corner area CS2 of the peripheral display area PSA, a third alignment mark ALM3 disposed adjacent to a third corner point VT3 of the main area MA and the third corner area CS3 of the peripheral display area PSA, and a fourth alignment mark ALM4 disposed adjacent to a fourth corner point VT4 of the main area MA and the fourth corner area CS4 of the peripheral display area PSA.

Such alignment marks ALMS may be used as alignment references during an alignment process between the display panel 100 and the cover window 300 (see FIG. 2).

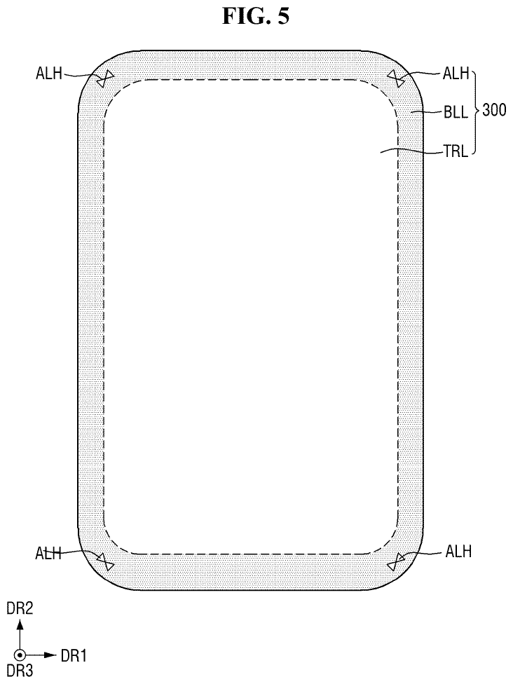

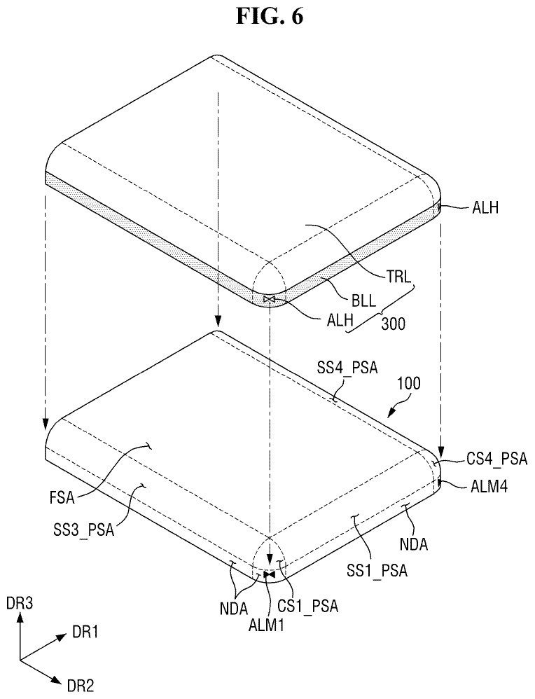

FIG. 5 is a plan view illustrating a cover window of FIG. 2. FIG. 6 is a view illustrating an alignment process between the display panel and the cover window according to embodiments.

As illustrated in FIG. 5, the cover window 300 of the display device 10 according to embodiments may include a light transmitting portion TRL through which light transmits and a light blocking portion BLL of an edge disposed around the light transmitting portion TRL.

The light transmitting portion TRL may overlap the display area DA (see FIG. 3) of the display panel 100 (see FIG. 3). Accordingly, light may be emitted from the display area DA (see FIG. 3) of the display panel 100 (see FIG. 3) to the outside through the light transmitting portion TRL to display an image.

The light blocking portion BLL may overlap the non-display area NDA (see FIG. 2), which is an area other than the display area DA of the display device 10. In such an embodiment, light emission in the non-display area NDA may be reduced by the light blocking portion BLL.

The cover window 300 may be provided with alignment holes ALH corresponding to the alignment marks ALMS of the display panel 100 (see FIG. 3).

The alignment holes ALH may be holes defined or formed through the light blocking portion BLL.

Referring to FIG. 6, in the alignment process between the display panel 100 and the cover window 300, the cover window 300 may be disposed in parallel with the display panel 100 in the third direction DR3 on the display panel 100. In this process, in the third direction DR3, it may be decided whether a position of the cover window 300 with respect to the display panel 100 is normal or not through whether or not the alignment marks ALMS of the display panel 100 are all viewed through the alignment holes ALH of the cover window 300.

According to embodiments, the display panel 100 includes the first alignment mark ALM1, the second alignment mark ALM2, the third alignment mark ALM3, and the fourth alignment mark ALM4 respectively adjacent to the first corner area CS1, the second corner area CS2, the third corner area CS3, and the fourth corner area CS4, and the cover window 300 includes four alignment holes ALH respectively corresponding to the four alignment marks ALMS of the display panel 100.

Therefore, even though the peripheral display area PSA of the edge of the display area DA is transformed into the curved shape, alignment between the display panel 100 and the cover window 300 may be performed at four corners of the main area MA having a quadrangular shape, such that a process error in the alignment process between the display panel 100 and the cover window 300 may be reduced.

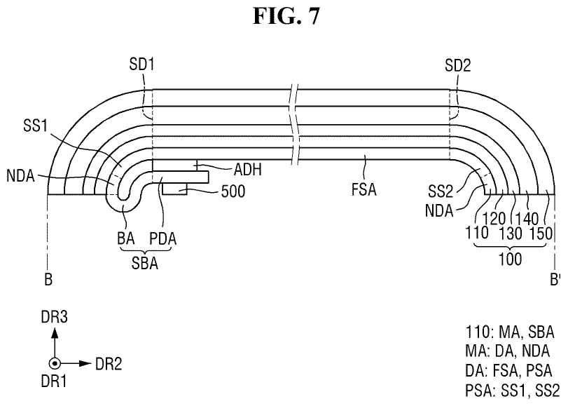

FIG. 7 is a cross-sectional view of the display panel taken along line B-B′ of FIG. 1.

Referring to FIG. 7, the display panel 100 of the display device 10 according to embodiments may include a substrate 110, a circuit layer 120 disposed on the substrate 110, and an element layer 130 disposed on the circuit layer 120.

The substrate 110 may include a main area MA and a sub-area SBA.

The main area MA may include a display area DA and a non-display area NA disposed around the display area DA.

The display area DA may include a front display area FSA and a peripheral display area PSA disposed around the front display area FSA and having a curved shape.

An edge of the front display area FSA may include a first side SD1 and a second side SD2 that oppose each other in the second direction DR2.

The peripheral display area PSA may include a first side area SS1 disposed between the first side SD1 of the front display area FSA and the non-display area NDA and a second side area SS2 disposed between the second side SD2 of the front display area FSA and the non-display area NDA.

In addition, as illustrated in FIG. 3, the edge of the front display area FSA may further include a third side SD3 and a fourth side SD4 that oppose each other in the first direction DR1.

The peripheral display area PSA may include a third side area SS3 disposed between the third side SD3 of the front display area FSA and the non-display area NDA and a fourth side area SS4 disposed between the fourth side SD4 of the front display area FSA and the non-display area NDA.

In addition, the peripheral display area PSA may further include a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

According to embodiments, the display device 10 may further include a display driving circuit 500 provided as an integrated circuit (IC) chip and mounted in the pad area PDA of the sub-area SBA of the substrate 110.

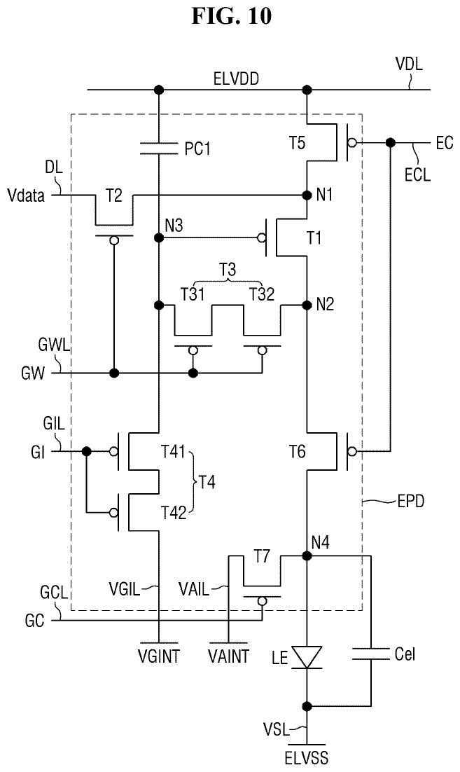

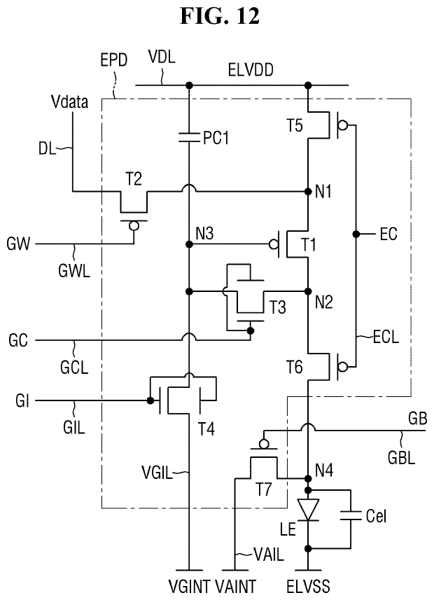

The display driving circuit 500 may supply data signals Vdata (see FIGS. 10 and 12) to data lines DL (see FIGS. 10 and 12) of the circuit layer 120.

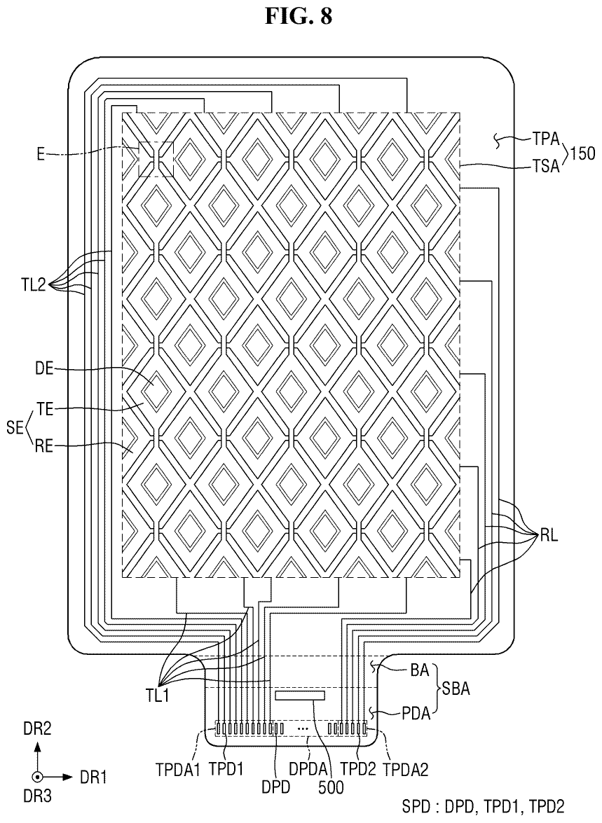

According to embodiments, the display device 10 may further include a circuit board bonded to the pad area PDA of the sub-area SBA of the substrate 110. The circuit board may be bonded to pads SPD (see FIG. 8) disposed in the sub-area SBA of the substrate 110 using a low-resistance and high-reliability material such as an anisotropic conductive film or a self assembly anisotropic conductive paste (SAP).

As illustrated in FIG. 4, the emission areas EA may be arranged in the display area DA.

The circuit layer 120 (see FIG. 7) may include emission pixel drivers EPD arranged side by side in the first direction DR1 and the second direction DR2.

As illustrated in FIG. 7, the element layer 130 may include light emitting elements LE (see FIGS. 10, 11, 12, and 13) respectively disposed in the emission areas EA.

The emission pixel drivers EPD (see FIG. 4) of the circuit layer 120 may be electrically connected to the light emitting elements LE (see FIGS. 10, 11, 12, and 13) of the element layer 130.

According to embodiments, the display panel 100 may further include a sealing layer 140 disposed on the element layer 130 and a touch sensor layer 150 disposed on the sealing layer 140.

The sealing layer 140 may be disposed on the element layer 130, and may have a structure in which two or more inorganic films and at least one organic film are alternately stacked.

The touch sensor layer 150 may include touch electrodes for detecting a signal varying depending on a touch of a person or an object to sense a point of the main area MA where the touch of the person or the object has occurred.

According to embodiments, the display panel 100 may prevent deterioration of visibility of an image due to external light reflection by blocking external light reflected from the touch sensor layer 150, the sealing layer 140, the element layer 130, and the circuit layer 120 and interfaces between these layers.

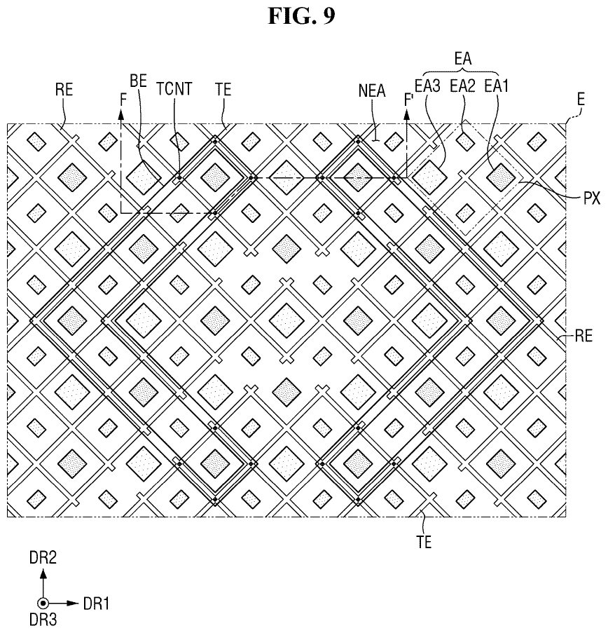

FIG. 8 is a schematic plan view illustrating a touch sensor layer of FIG. 7 according to embodiments. FIG. 9 is an enlarged plan view illustrating portion E of FIG. 8.

FIGS. 8 and 9 illustrate an embodiment where the touch sensor layer is a capacitance-type touch sensor layer 150. In such an embodiment, the display device 10 may further include a touch driving circuit for sensing a touch based on whether there is or not a change in capacitance. The touch driving circuit may be mounted on the pad area PDA of the substrate 110 or on the circuit board. However, embodiments shown in FIGS. 8 and 9 are only an example for convenience of description, and the touch sensor layer 150 according to an embodiment is not limited to those illustrated in FIGS. 8 and 9.

FIG. 8 illustrates only some of components of the touch sensor layer 150 for convenience of illustration and description.

Referring to FIG. 8, the touch sensor layer 150 may be disposed on the main area MA of the substrate 110. The touch sensor layer 150 may include a touch sensing area TSA for sensing a user's touch and a touch peripheral area TPA disposed around the touch sensing area TSA.

The touch sensing area TSA may be wider than the display area DA and may be similar to the display area DA. Accordingly, the touch peripheral area TPA, which is a peripheral area of the touch sensing area TSA, may be similar to the non-display area NDA, which is a peripheral area of the display area DA.

In an embodiment, for example, the touch sensing area TSA may overlap the display area DA and an edge of the non-display area NDA in contact with the display area DA. In such an embodiment, the touch peripheral area TPA may overlap the remaining portion of the non-display area NDA that does not correspond to the touch sensing area TSA.

The touch sensor layer 150 may include sensor electrodes SE and dummy electrodes DE arranged in a matrix form in the touch sensing area TSA and generating mutual capacitance and sensor lines TL1, TL2, and RL disposed in the touch peripheral area TPA.

The sensor electrodes SE may include touch driving electrodes TE to which touch driving signals are applied and receiving electrodes RE for sensing voltages charged in mutual capacitance with the touch driving electrodes TE.

The sensor lines may include first driving lines TL1, second driving lines TL2, and sensing lines RL.

Each of the first driving lines TL1 and the second driving lines TL2 may be electrically connected to two or more touch driving electrodes TE connected to each other in the second direction DR2 among the touch driving electrodes TE.

The first driving lines TL1 may extend from one side of an edge of the touch sensing area TSA which extends in the first direction DR1 and is adjacent to the sub-area SBA, to reach the sub-area SBA.

The second driving lines TL2 may extend from other side of an edge of the touch sensing area TSA which extends in the first direction DR1 and is spaced apart from the sub-area SBA, and in parallel with one side of the edge of the touch sensing area TSA which extends in the second direction DR2, to reach the sub-area SBA.

The sensing lines RL may be electrically connected to two or more receiving electrodes RE connected to each other in the first direction DR1 among the receiving electrodes RE.

The receiving electrodes RE may be arranged side by side in the first direction DR1. The receiving electrodes RE neighboring to each other in the first direction DR1 may be electrically connected to each other through protruding portions in the first direction DR1.

The touch driving electrodes TE may be arranged side by side in the second direction DR2. The touch driving electrodes TE neighboring to each other in the second direction DR2 may be electrically connected to each other through bridge electrodes BE (see FIG. 9) in the second direction DR2.

Each of the touch driving electrodes TE and the receiving electrodes RE may have a shape in which it surrounds the dummy electrode DE disposed at the center thereof.

Each of the dummy electrodes DE may be spaced apart from the touch driving electrode TE and the receiving electrode RE surrounding each of the dummy electrodes DE. The dummy electrode DE may be maintained in a floating state.

FIG. 8 illustrates an embodiment where each of the touch driving electrodes TE, the receiving electrodes RE, and the dummy electrodes DE has a rhombic shape in the plan view, but an embodiment is not limited to that illustrated in FIG. 8. In an embodiment, for example, a shape of each of the touch driving electrodes TE, the receiving electrodes RE, and the dummy electrodes DE in the plan view may be a quadrangular shape other than the rhombic shape, a polygonal shape other than the quadrangular shape, a circular shape, or an elliptical shape. According to embodiments, the display panel 100 may include signal pads SPD which

are disposed in the pad area PDA of the sub-area SBA of the substrate 110 and to which the circuit board is connected.

In an embodiment, for example, the display driving circuit 500 may be mounted in the pad area PDA.

The pad area PDA may include a display pad area DPDA adjacent to the display driving circuit 500 and a first touch pad area TPDA1 and a second touch pad area TPDA2 disposed on both sides of the display pad area DPDA, respectively.

The signal pads SPD may include display signal pads DPD disposed in the display pad area DPDA and first touch pads TPD1 and second touch pads TPD2 disposed in the first touch pad area TPDA1 and the second touch pad area TPDA2, respectively.

The display signal pads DPD may be electrically connected to the circuit layer 120 or the display driving circuit 500.

The first touch pads TPD1 may be electrically connected to the first driving lines TL1 and the second driving lines TL2.

The second touch pads TPD2 may be electrically connected to the sensing lines RL.

Referring to FIG. 9, the touch sensor layer 150 may further include bridge electrodes BE electrically connecting the touch driving electrodes TE neighboring to each other in the second direction DR2 to each other.

The bridge electrodes BE may be electrically connected to the touch driving electrodes TE through touch electrode connection holes TCNT.

The touch driving electrodes TE neighboring to each other in the second direction DR2 may be electrically connected to each other through two or more bridge electrodes BE. In this way, reliability of the electrical connection between the touch driving electrodes TE may be improved.

FIG. 9 illustrates an embodiment where two bridge electrodes BE parallel to each other are disposed between the touch driving electrodes TE neighboring to each other in the second direction DR2, but an embodiment is not limited to that illustrated in FIG. 9.

FIG. 9 illustrates the bridge electrode BE having a shape including one bend, but a shape of the bridge electrode BE according to an embodiment is not limited to that illustrated in FIG. 9.

The touch driving electrode TE and the receiving electrode RE may be spaced apart from each other.

The bridge electrode BE may be disposed at a different conductive layer from the touch driving electrode TE and the receiving electrode RE.

Each of the touch driving electrodes TE, the receiving electrodes RE, and the bridge electrodes BE may have a mesh shape or a shape of a net structure in the plan view. The dummy electrodes DE may also have a mesh shape or a shape of a net structure in the plan view. In this way, widths of the emission areas EA overlapping the touch driving electrodes TE, the receiving electrodes RE, the dummy electrodes DE, and the bridge electrodes BE may be reduced, and thus, a decrease degree of light emission efficiency of the emission areas EA due to the touch driving electrodes TE, the receiving electrodes RE, the dummy electrodes DE, and the bridge electrodes BE may be alleviated.

FIG. 10 is an equivalent circuit diagram illustrating an emission pixel driver of FIG. 4 according to an embodiment.

Referring to FIG. 10, the emission pixel drivers EPD of the circuit layer 120 may be electrically connected between a first power source ELVDD and the light emitting elements LE of the element layer 130. One light emitting element LE of the light emitting elements LE of the element layer 130 may be electrically connected between one emission pixel driver EPD of the emission pixel drivers EPD of the circuit layer 120 and a second power source ELVSS.

In an embodiment, an anode electrode of the light emitting element LE may be electrically connected to the emission pixel driver EPD, and second power ELVSS having a lower voltage level than first power ELVDD may be applied to a cathode electrode of the light emitting element LE.

A capacitor Ce1 connected to the light emitting element LE in parallel indicates parasitic capacitance between the anode electrode and the cathode electrode.

The circuit layer 120 may include a first power line VDL that transfers the first power ELVDD, a gate initialization voltage line VGIL that transfers a gate initialization voltage VGINT, and an anode initialization voltage line VAIL that transfers an anode initialization voltage VAINT.

The circuit layer 120 may further include a scan write line GWL that transfers a scan write signal GW, a scan initialization line GIL that transfers a scan initialization signal GI, an emission control line ECL that transfers an emission control signal EC, and a gate control line GCL that transfers a gate control signal GC.

One emission pixel driver EPD of the circuit layer 120 may include a first transistor T1 that generates a driving current for driving the light emitting element LE, two or more transistors T2 to T7 electrically connected to the first transistor T1, and at least one capacitor PC1.

The first transistor T1 may be electrically connected between a first node N1 and a second node N2. The first node N1 is electrically connected to a first electrode (e.g., a source electrode) of the first transistor T1. The second node N2 is electrically connected to a second electrode (e.g., a drain electrode) of the first transistor T1.

The first node N1 may be electrically connected to the first power line VDL through a fifth transistor T5.

The second node N2 may be electrically connected to the anode electrode of the light emitting element LE through a sixth transistor T6.

A pixel capacitor PC1 may be electrically connected between the first power line VDL and a third node N3. The third node N3 is electrically connected to a gate electrode of the first transistor T1.

That is, the gate electrode of the first transistor T1 may be electrically connected to the first power line VDL through the pixel capacitor PC1.

Accordingly, a potential of the gate electrode of the first transistor T1 may be maintained as a voltage charged in the pixel capacitor PC1.

A second transistor T2 may be electrically connected between a data line DL and the first node N1.

The second transistor T2 may be electrically connected between the first electrode of the first transistor T1 and the data line DL.

That is, the first electrode of the first transistor T1 may be electrically connected to the data line DL through the second transistor T2.

The second transistor T2 may be turned on by the scan write signal GW of the scan write line GWL.

The fifth transistor T5 may be electrically connected between the first node N1 and the first voltage line VDL.

The sixth transistor T6 may be electrically connected between the second node N2 and a fourth node N4. The fourth node N4 is electrically connected to the anode electrode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When a data signal Vdata of the data line DL is transferred to the first electrode of the first transistor T1 through the turned-on second transistor T2, a voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, that is, a gate-source voltage difference, is greater than or equal to a threshold voltage, the first transistor T1 is turned on, such that a drain-source current of the first transistor T1 corresponding to the data signal Vdata may be generated.

Subsequently, when the fifth transistor T5 and the sixth transistor T6 are turned on, the first power source ELVDD, the first transistor T1, the light emitting element LE, and the second power source ELVSS may be connected to each other in series. Accordingly, the drain-source current of the first transistor T1 corresponding to the data signal Vdata may be supplied as the driving current of the light emitting element LE.

Accordingly, the light emitting element LE may emit light of luminance corresponding to the data signal Vdata.

A third transistor T3 may be electrically connected between the second node N2 and the third node N3. That is, the third transistor T3 may be electrically connected between the gate electrode of the first transistor T1 and the second electrode of the first transistor T1.

The third transistor T3 may include a plurality of sub-transistors connected to each other in series. In an embodiment, for example, the third transistor T3 may include a first sub-transistor T31 and a second sub-transistor T32.

A first electrode of the first sub-transistor T31 may be connected to the gate electrode of the first transistor T1, a second electrode of the first sub-transistor T31 may be connected to a first electrode of the second sub-transistor T32, and a second electrode of the second sub-transistor T32 may be connected to the second electrode of the first transistor T1.

In such an embodiment, the potential of the gate electrode of the first transistor T1 may be effectively prevented from changing due to a leakage current caused by the third transistor T3 that is not turned on.

The first sub-transistor T31 and the second sub-transistor T32 may be turned on by the scan write signal GW of the scan write line GWL.

When the first sub-transistor T31 and the second sub-transistor T32 are turned on, a voltage difference between the second node N2 and the third node N3 may be initialized.

A fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may include a plurality of sub-transistors connected to each other in series. In an embodiment, for example, the fourth transistor T4 may include a third sub-transistor T41 and a fourth sub-transistor T42.

A first electrode of the third sub-transistor T41 may be connected to the gate electrode of the first transistor T1, a second electrode of the third sub-transistor T41 may be connected to a first electrode of the fourth sub-transistor T42, and a second electrode of the fourth sub-transistor T42 may be connected to the gate initialization voltage line VGIL.

In such an embodiment, the potential of the gate electrode of the first transistor T1 may be effectively prevented from changing due to a leakage current caused by the fourth transistor T4 that is not turned on.

The third sub-transistor T41 and the fourth sub-transistor T42 may be turned on by the scan initialization signal GI of the scan initialization line GIL.

When the third sub-transistor T41 and the fourth sub-transistor T42 are turned on, a potential of the third node N3 may be initialized to the gate initialization voltage VGINT.

A seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL.

The seventh transistor T7 may be turned on by the gate control signal GC of the gate control line GCL.

Through the turned-on seventh transistor T7, a potential of the fourth node N4 may be initialized to the anode initialization voltage VAINT.

As illustrated in FIG. 10, according to an embodiment, the first to seventh transistors T1 to T7 may be provided as P-type metal oxide semiconductor field effect transistors (MOSFETs), but not being limited thereto.

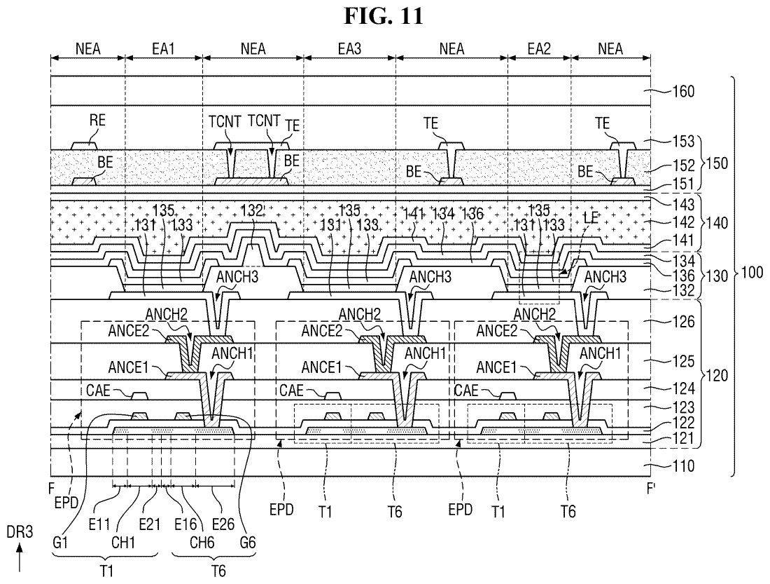

FIG. 11 is a cross-sectional view taken along line F-F′ of FIG. 9 according to an embodiment of FIG. 10.

Referring to FIG. 11, the display panel 100 of the display device 10 according to embodiments may include a substrate 110, a circuit layer 120 disposed on the substrate 110, and an element layer 130 disposed on the circuit layer 120.

The display panel 100 of the display device 10 according to embodiments may further include a sealing layer 140 disposed on the element layer 130, a touch sensor layer 150 disposed on the sealing layer 140, and a polarizing layer 160 disposed on the touch sensor layer 150.

The circuit layer 120 may include an interlayer insulating layer 124 disposed on the substrate 110, a first source/drain conductive layer ANCE1 disposed on the interlayer insulating layer 124, a first planarization layer 125 covering the first source/drain conductive layer, a second source/drain conductive layer DL and ANCE2 disposed on the first planarization layer 125, and a second planarization layer 126 covering the second source/drain conductive layer.

According to an embodiment, the circuit layer 120 may further include a first semiconductor layer CH1, E11, E21, CH6, E16, and E26 disposed on the substrate 110, a first gate insulating layer 122 covering the first semiconductor layer, a first gate conductive layer G1 and G6 disposed on the first gate insulating layer 122, a second gate insulating layer 123 covering the first gate conductive layer, and a second gate conductive layer CAE disposed on the second gate insulating layer 123.

According to an embodiment, the interlayer insulating layer 124 may be disposed on the second gate insulating layer 123 and cover the second gate conductive layer.

The circuit layer 120 may further include a buffer layer 121 covering the substrate 110.

In an embodiment, the first semiconductor layer CH1, E11, E21, CH6, E16, and E26 may be disposed on the buffer layer 121.

The circuit layer 120 may include emission pixel drivers EPD respectively corresponding to the emission areas EA.

Each of the emission pixel drivers EPD may include a first transistor T1, second to seventh transistors T2 to T7 (see FIG. 10) electrically connected to the first transistor T1, and at least one capacitor PC1 (see FIG. 10).

FIG. 11 illustrates a portion corresponding to the first transistor T1, the sixth transistor T6, and the light emitting element LE of the emission pixel driver EPD of FIG. 10.

The first semiconductor layer disposed on the buffer layer 121 may include channel portions CH1 and CH6, first electrode portions E11 and E16, and second electrode portions E21 and E26 of each of the first to seventh transistors T1 to T7.

In each of the first transistor T1 and the sixth transistor T6, the first electrode portions E11 and E16 may be connected to one ends of the channel portions CH1 and CH6, and the second electrode portions E21 and E26 may be connected to other ends of the channel portions CH1 and CH6.

The second electrode portion E21 of the first transistor T1 may be connected to the first electrode portion E16 of the sixth transistor T6.

The first gate conductive layer disposed on the first gate insulating layer 122 may include gate electrodes G1 and G6 of each of the first to seventh transistors T1 to T7.

In each of the first transistor T1 and the sixth transistor T6, the gate electrodes G1 and G6 may overlap the channel portions CH1 and CH6, respectively.

The second transistor T2, the first sub-transistor T31, the second sub-transistor T32, the third sub-transistor T41, the fourth sub-transistor T42, the fifth transistor T5, and the seventh transistor T7 of the emission pixel driver EPD of FIG. 10 are provided as a same P-type MOSFETs as the first transistor T1 and the sixth transistor T6, and any repetitive detailed description thereof will thus be omitted below.

The second gate conductive layer disposed on the second gate insulating layer 123 may include capacitor electrodes CAE.

The capacitor electrode CAE may overlap the gate electrode G1 of the first transistor T1.

Accordingly, the pixel capacitor PC1 (see FIG. 10) may be provided by an overlap area between the capacitor electrode CAE and the gate electrode G1 of the first transistor T1.

The first source/drain conductive layer disposed on the interlayer insulating layer 124 may include first anode connection electrodes ANCE1.

The first anode connection electrode ANCE1 may be electrically connected to the second electrode portion E26 of the sixth transistor T6 through a first anode connection hole ANCH1.

The second source/drain conductive layer disposed on the first planarization layer 125 may include second anode connection electrodes ANCE2.

The second anode connection electrode ANCE2 may be electrically connected to the first anode connection electrode ANCE1 through a second anode connection hole ANCH2.

An anode electrode 131 of the element layer 130 may be disposed on the second planarization layer 126, and may be electrically connected to the second anode connection electrode ANCE2 through a third anode contact hole ANCT3.

Accordingly, the anode electrode 131 may be electrically connected to the second electrode portion E26 of the sixth transistor T6 through the first anode connection electrode ANCE1 and the second anode connection electrode ANCE2.

The element layer 130 disposed on the circuit layer 120 may include the light emitting elements LE respectively disposed in the emission areas EA1, EA2, and EA3.

Each of the light emitting elements LE may have a structure in which a light emitting layer 133 disposed between the anode electrode 131 and a cathode electrode 134 facing each other.

According to embodiments, the element layer 130 may include anode electrodes 131 respectively disposed in the emission areas EA, a pixel defining layer 132 disposed in a non-emission area NEA and covering edges of the anode electrodes 131, a spacer layer 132′ disposed on a portion of the pixel defining layer 132, light emitting layers 133 respectively disposed on the anode electrodes 131, and a cathode electrode 134 disposed on the light emitting layers 133, the pixel defining layer 132, and the spacer layer 132′.

Alternatively, the light emitting elements LE may further include first common layers 135 disposed between the anode electrodes 131 and the light emitting layers 133 and a second common layer 136 disposed between the light emitting layers 133 and the cathode electrode 134, respectively.

The sealing layer 140 may cover the element layer 130.

The sealing layer 140 may block permeation of oxygen or moisture into the element layer 130 and alleviate an electrical or physical shock to the circuit layer 120 and the element layer 130.

The sealing layer 140 may include a first sealing layer 141 covering the element layer 130, and including an inorganic insulating material, a second sealing layer 142 disposed on the first sealing layer 141, overlapping the element layer 130, and including an organic insulating material, and a third sealing layer 143 disposed on the first sealing layer 141, covering the second sealing layer 142, and including an inorganic insulating material.

The touch sensor layer 150 may be disposed on the sealing layer 140.

The touch sensor layer 150 may include a touch buffer layer 151 disposed on the sealing layer 140, a first touch conductive layer BE disposed on the touch buffer layer 151, a touch interlayer insulating layer 152 covering the first touch conductive layer, a second touch conductive layer RE and TE disposed on the touch interlayer insulating layer 152, and a touch planarization layer 153 covering the second touch conductive layer.

The first touch conductive layer disposed on the touch buffer layer 151 may include the bridge electrodes BE.

The second touch conductive layer disposed on the touch interlayer insulating layer 152 may include the touch driving electrodes TE and the receiving electrodes RE.

The dummy electrodes DE disposed inside each of the touch driving electrodes TE and the receiving electrodes RE, the first driving lines TL1 and the second driving lines TL2 connected to the touch driving electrodes TE, and the sensing lines RL connected to the receiving electrodes RE may be disposed at the second touch conductive layer disposed on the touch interlayer insulating layer 152, like the touch driving electrodes TE and the receiving electrodes RE.

The touch driving electrode TE may be electrically connected to the bridge electrode BE through the touch electrode connection hole TCNT defined or formed through the touch interlayer insulating layer 152.

The touch buffer layer 151 may include an inorganic insulating material.

According to an embodiment, each of the touch interlayer insulating layer 152 and the touch planarization layer 153 may include an organic insulating material.

The polarizing layer 160 may be disposed on touch sensor layer 150.

In an embodiment, the emission pixel driver EPD of FIG. 10 includes the first to seventh transistors T1 to T7 provided as the P-type MOSFETs. However, this is only an example, and some of the first to seventh transistors T1 to T7 may also be provided as N-type MOSFETs. In an embodiment, for example, the third transistor T3 and the fourth transistor T4 may be provided as N-type MOSFETs.

FIG. 12 is an equivalent circuit diagram illustrating an emission pixel driver of FIG. 4 according to an embodiment.

A circuit layer 120 of a display panel 100 according to an embodiment of FIG. 12 is substantially the same as the circuit layer 120 of the display panel 100 according to an embodiment illustrated in FIG. 10 except that the third transistor T3 and the fourth transistor T4 of the first to seventh transistors T1 to T7 of the emission pixel driver EPD are provided as N-type MOSFETs, and any repetitive detailed description of the same or like elements as those described above with reference to FIG. 10 will thus be omitted below.

According to an embodiment of FIG. 12, the third transistor T3 may be electrically connected between the second node N2 and the third node N3. That is, the third transistor T3 may be electrically connected between the gate electrode of the first transistor T1 and the second electrode of the first transistor T1.

The third transistor T3 is provided as the N-type MOSFET, and accordingly, may be turned on by the gate control signal GC of the gate control line GCL.

A voltage difference between the second node N2 and the third node N3 may be initialized through the turned-on third transistor T3.

In such an embodiment, the seventh transistor T7 may be turned on by a bias control signal GB of a bias control line GBL rather than the gate control signal GC of the gate control line GCL.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may be turned on by the scan initialization signal GI of the scan initialization line GIL.

A potential of the third node N3 may be initialized through the turned-on fourth transistor T4.

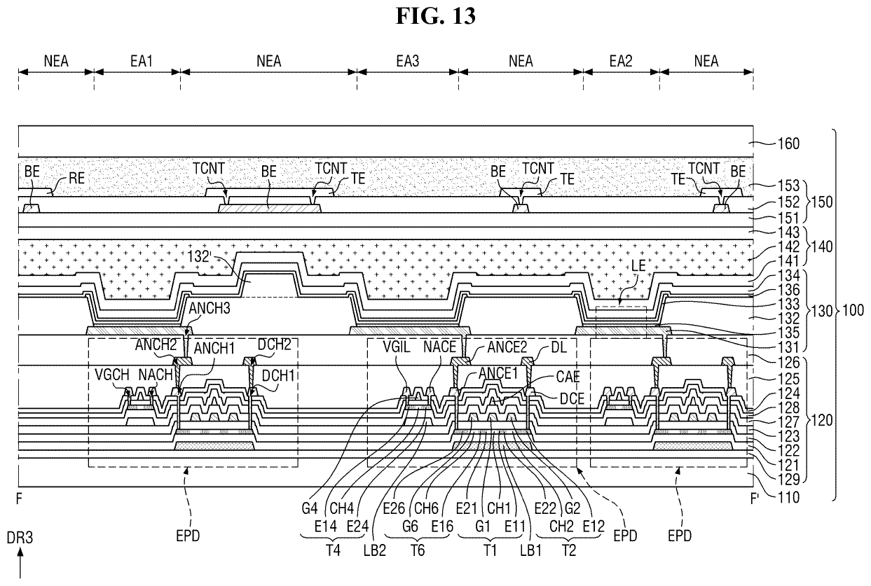

FIG. 13 is a cross-sectional view taken along line F-F′ of FIG. 9 according to an embodiment of FIG. 12.

The circuit layer 120 of the display panel 100 according to an embodiment of FIG. 13 is substantially the same as the circuit layer 120 of the display panel 100 according to an embodiment illustrated FIG. 11 except that the circuit layer 120 further includes a second semiconductor layer CH4, E14, and E24 and a third gate conductive layer G4 for providing the N-type MOSFET, an auxiliary interlayer insulating layer 127, and a third gate insulating layer 128, and any repetitive detailed description of the same or like elements as those described above with reference to FIG. 11 will thus be omitted or simplified below.

FIG. 13 illustrates a portion corresponding to the first transistor T1, the second transistor T2, and the sixth transistor T6 provided as the P-type MOSFETs and the fourth transistor T4 provided as the N-type MOSFET among the transistors T1 to T7 (see FIG. 12) of the emission pixel driver EPD and the light emitting element LE.

According to an embodiment of FIG. 13, the circuit layer 120 may include an interlayer insulating layer 124 disposed on the substrate 110, a first source/drain conductive layer ANCE1, VGIL, and DCE disposed on the interlayer insulating layer 124, a first planarization layer 125 covering the first source/drain conductive layer, a second source/drain conductive layer DL and ANCE2 disposed on the first planarization layer 125, and a second planarization layer 126 covering the second source/drain conductive layer.

According to an embodiment of FIG. 13, the circuit layer 120 may further include a first semiconductor layer CH1, E11, E21, CH2, E12, E22, CH6, E16, and E26 disposed on the substrate 110, a first gate insulating layer 122 covering the first semiconductor layer, a first gate conductive layer G1, G2, and G6 disposed on the first gate insulating layer 122, a second gate insulating layer 123 covering the first gate conductive layer, and a second gate conductive layer CAE and LB2 disposed on the second gate insulating layer 123.

According to an embodiment of FIG. 13, the circuit layer 120 may further include the auxiliary interlayer insulating layer 127 covering the second gate conductive layer, the second semiconductor layer CH4, E14, and E24 disposed on the auxiliary interlayer insulating layer 127, the third gate insulating layer 128 covering the second semiconductor layer, and the third gate conductive layer G4 disposed on the third gate insulating layer 128 and covered with the interlayer insulating layer 124.

According to an embodiment illustrated in FIG. 13, the circuit layer 120 may further include a barrier layer 129 disposed on the substrate 110 and a first light blocking layer LB1 disposed on the barrier layer 129 and covered with the buffer layer 121.

The first semiconductor layer disposed on the buffer layer 121 may include channel portions CH1, CH2, and CH6, first electrode portions E11, E12, and E16, and second electrode portions E21, E22, and E26 of each of the first transistor T1, the second transistor T2, the fifth transistor T5 (see FIG. 12), the sixth transistor T6, and the seventh transistor T7 (see FIG. 12) provided as the P-type MOSFETs.

The first gate conductive layer disposed on the first gate insulating layer 122 may include gate electrodes G1, G2, and G6 of each of the first transistor T1, the second transistor T2, the fifth transistor T5 (see FIG. 12), the sixth transistor T6, and the seventh transistor T7 (see FIG. 12) provided as the P-type MOSFETs.

The fifth transistor T5 and the seventh transistor T7 have the same structure as the first transistor T1, the second transistor T2, and the sixth transistor T6, and any repetitive detailed description thereof will thus be omitted below.

In each of the first transistor T1, the second transistor T2, and the sixth transistor T6, the channel portions CH1, CH2, and CH6 may overlap the gate electrodes G1, G2, and G6, respectively.

The channel portion CH1 of the first transistor T1 may overlap the first light blocking layer LB1 disposed below the buffer layer 121.

In each of the first transistor T1, the second transistor T2, and the sixth transistor T6, the first electrode portions E11, E12, and E16 may be connected to one ends of the channel portions CH1, CH2, and CH6, and the second electrode portions E21, E22, and E26 may be connected to the other ends of the channel portions CH1, CH2, and CH6.

The first electrode portion E11 of the first transistor T1 may be connected to the second electrode portion E22 of the second transistor T2.

The second electrode portion E21 of the first transistor T1 may be connected to the first electrode portion E16 of the sixth transistor T6.

The second gate conductive layer disposed on the second gate insulating layer 123 may include capacitor electrodes CAE and a second light blocking layer LB2.

The second semiconductor layer disposed on the auxiliary interlayer insulating layer 127 may include a channel portion CH4, a first electrode portion E14, and a second electrode portion E24 of each of the third transistor T3 (see FIG. 12) and the fourth transistor T4 provided as the N-type MOSFETs.

The third gate conductive layer disposed on the third gate insulating layer 128 may include a gate electrode G4 of each of the third transistor T3 (see FIG. 12) and the fourth transistor T4 provided as the N-type MOSFETs.

In each of the third transistor T3 (see FIG. 12) and the fourth transistor T4, the channel portion CH4 may overlap the second light blocking layer LB2 disposed below the auxiliary interlayer insulating layer 127.

The channel portion CH4 of the fourth transistor T4 may overlap the gate electrode G4 of the fourth transistor T4.

The first electrode portion E14 of the fourth transistor T4 may be connected to one end of the channel portion CH4 of the fourth transistor T4, and the second electrode portion E24 of the fourth transistor T4 may be connected to the other end of the channel portion CH4 of the fourth transistor T4.

The third transistor T3 is provided as the same N-type MOSFET as the fourth transistor T4, and an overlapping description will thus be omitted below.

The first source/drain conductive layer disposed on the interlayer insulating layer 124 may include first anode connection electrodes ANCE1, data connection electrodes DCE, gate initialization voltage lines VGIL, and node auxiliary connection electrodes NACE.

The second source/drain conductive layer disposed on the first planarization layer 125 may include second anode connection electrodes ANCE2 and data lines DL.

The data connection electrode DCE may be electrically connected to the first electrode portion E12 of the second transistor T2 through a first data connection hole DCH1. The data line DL may be electrically connected to the data connection electrode DCE

through a second data connection hole DCH2.

Accordingly, the data line DL may be electrically connected to the first electrode portion E12 of the second transistor T2 through the data connection electrode DCE.

The gate initialization voltage line VGIL may be electrically connected to the first electrode portion E14 of the fourth transistor T4 through a gate initialization voltage connection hole VGCH.

The node auxiliary connection electrode NACE may be electrically connected to the second electrode portion E24 of the fourth transistor T4 through a node auxiliary connection hole NACH.

The element layer 130, the sealing layer 140, the touch sensor layer 150, and the polarizing layer 160 of the display panel 100 according to an embodiment illustrated in FIG. 13 are substantially the same as those of the display panel 100 according to an embodiment illustrated in FIG. 11, and any repetitive detailed description thereof will thus be omitted below.

FIG. 14 is a plan view illustrating portion D of FIG. 3 according to an embodiment. As illustrated in FIG. 3, the substrate 110 of the display panel 100 of the display device 10 according to embodiments may include a display area DA and a non-display area NDA, and the display area DA may include a front display area FSA and a peripheral display area PSA disposed around the front display area FSA and having a curved shape.

The peripheral display area PSA may include a first side area SS1 in contact with the first side SD1 of the front display area FSA, a second side area SS2 in contact with the second side SD2 of the front display area FSA, a third side area SS3 in contact with the third side SD3 of the front display area FSA, a fourth side area SS4 in contact with the fourth side SD4 of the front display area FSA, a first corner area CS1 in contact with a vertex where the first side SD1 and the third side SD3 are connected to each other and disposed between the first side area SS1 and the third side area SS3, a second corner area CS2 in contact with a vertex where the second side SD2 and the third side SD3 are connected to each other and disposed between the second side area SS2 and the third side area SS3, a third corner area CS3 in contact with a vertex where the second side SD2 and the fourth side SD4 are connected to each other and disposed between the second side area SS2 and the fourth side area SS4, and a fourth corner area CS4 in contact with a vertex where the first side SD1 and the fourth side SD4 are connected to each other and disposed between the first side area SS1 and the fourth side area SS4.

The circuit layer 120 of the display panel 100 of the display device 10 according to embodiments may include four alignment marks ALMS: ALM1, ALM2, ALM3, and ALM4 disposed in the non-display area NDA and disposed respectively adjacent to four corner points VT1, VT2, VT3, and VT1 of the main area MA.

The four alignment marks ALMS: ALM1, ALM2, ALM3, and ALM4 may include a first alignment mark ALM1 disposed adjacent to a first corner point VT1 of the main area MA and the first corner area CS1 of the peripheral display area PSA, a second alignment mark ALM2 disposed adjacent to a second corner point VT2 of the main area MA and the second corner area CS2 of the peripheral display area PSA, a third alignment mark ALM3 disposed adjacent to a third corner point VT3 of the main area MA and the third corner area CS3 of the peripheral display area PSA, and a fourth alignment mark ALM4 disposed adjacent to a fourth corner point VT4 of the main area MA and the fourth corner area CS4 of the peripheral display area PSA.

The non-display area NDA of the substrate 110 of the display panel 100 of the display device 10 according to embodiments may include a dam area DMA surrounding the display area DA and spaced apart from the display area DA.

FIG. 14 illustrates a corner portion including the second alignment mark ALM2 disposed adjacent to the second corner point VT2 of the main area MA and the second corner area CS2_PSA of the peripheral display area of the display area DA.

In such an embodiment, the first alignment mark ALM1, the third alignment mark ALM3, and the fourth alignment mark ALM4 disposed at portions of the non-display area NDA adjacent to the first corner point VT1, the third corner point VT3, and the fourth corner point VT4, respectively, are substantially the same as the second alignment mark ALM2 disposed adjacent to the second corner point VT2, and the first corner area CS1, the third corner area CS3, and the fourth corner area CS4 of the periphery display area PSA of the display area DA are substantially the same as the second corner area CS2, and any repetitive detailed description thereof will thus be omitted herein.

Referring to FIG. 14, the display panel 100 of the display device 10 according to embodiments may further include one or more dam portions DM1 and DM2 arranged in the dam area DMA of the non-display area NDA.

The circuit layer 120 of the display panel 100 of the display device 10 according to embodiments may further include a power supply line VSPL disposed in the non-display area NDA to transfer the power ELVDD or ELVSS (see FIGS. 10 and 12) for driving the light emitting elements LE (see FIGS. 10, 11, 12, and 13).

The power supply line VSPL may be disposed or formed to surround at least three sides of the edge of the display area DA, and may overlap the dam area DMA in the plan view.

The power supply line VSPL may transfer the first power ELVDD (see FIGS. 10 and 12) or the second power ELVSS (see FIGS. 10 and 12).

In an embodiment, for example, the power supply line VSPL may transfer the second power ELVSS (see FIGS. 10 and 12).

In another embodiment, for example, the power supply line VSPL may include a first power supply line that transfers the first power ELVDD (see FIGS. 10 and 12) and a second power supply line that transfers the second power ELVSS (see FIGS. 10 and 12).

According to embodiments, the alignment marks ALMS (see FIG. 3) including the second alignment mark ALM2 of the non-display area NDA may be spaced apart from the power supply line VSPL in a direction that becomes distant from the display area DA. That is, the alignment marks ALMS (see FIG. 3) including the second alignment mark ALM2 of the non-display area NDA may be disposed adjacent to an edge of the substrate 110.

Each of the alignment marks ALMS (see FIG. 3) including the second alignment mark ALM2 may include two or more keys EKY1, EKY2, and EKY3 spaced apart from each other.

Each of the two or more keys EKY1, EKY2, and EKY3 may have one of two or more different polygonal patterns or shapes. Alternatively, the two or more keys EKY1, EKY2, and EKY3 may have different patterns or shapes from each other.

In an embodiment, for example, a first key EKY1 of the two or more keys EKY1, EKY2, and EKY3 may have a ribbon pattern (or a ribbon-like shape) where two rhombuses are in contact with each other at vertices thereof, a second key EKY2 of the two or more keys EKY1, EKY2, and EKY3 may have a W pattern, and a third key EKY3 of the two or more keys EKY1, EKY2, and EKY3 may have a cross pattern.

The display panel 100 of the display device 10 according to embodiments may further include capping portions CPP overlapping the dam area DMA and spaced apart from the alignment marks ALMS (see FIG. 3) including the second alignment mark ALM2.

The capping portions CPP are used to protect an inorganic insulating material positioned at the uppermost end of one or more dam portions DM1 and DM2 arranged in the dam area DMA from an etching process for disposing the second touch conductive layer TE and DE (see FIGS. 11 and 13).

According to embodiments, one or more dam portions DM1 and DM2 arranged in the dam area DMA is provided to limit a diffusion range of the organic insulating material of the second sealing layer 142 of the sealing layer 140, and has a relatively great step from the substrate 110. However, the touch interlayer insulating layer 152 of the touch sensor layer 150 includes the organic insulating material, and thus, one or more dam portions DM1 and DM2 may not be completely covered with the touch interlayer insulating layer 152. In this case, an inorganic insulating material of portions (e.g., the touch buffer layer 151, the third sealing layer 143, and the first sealing layer 141) of one or more dam portions DM1 and DM2 that are not covered with the touch interlayer insulating layer 152 may be exposed to the etching process for disposing the second touch conductive layer TE and DE (see FIGS. 11 and 13) to be easily damaged.

In order to prevent such a damage to inorganic insulating material of portions of one or more dam portions DM1 and DM2, the display panel 100 according to embodiments may include the capping portions CPP overlapping the dam area DMA.

The capping portion CPP may be disposed at (in or directly on) a same layer as the first touch conductive layer BE (see FIGS. 11 and 13).

According to an embodiment, the capping portions CPP may be spaced apart from each other and may be spaced apart from the alignment marks ALMS (e.g., ALM2 in FIG. 3) such that the alignment marks ALMS (e.g., ALM2 in FIG. 3) may be effectively prevented from being hidden (or covered) by the capping portions CPP.

In such an embodiment, the capping portions CPP may be disposed in an island shape in which the capping portions CPP are spaced apart from the alignment marks ALMS (e.g., ALM2 in FIG. 3), respectively.

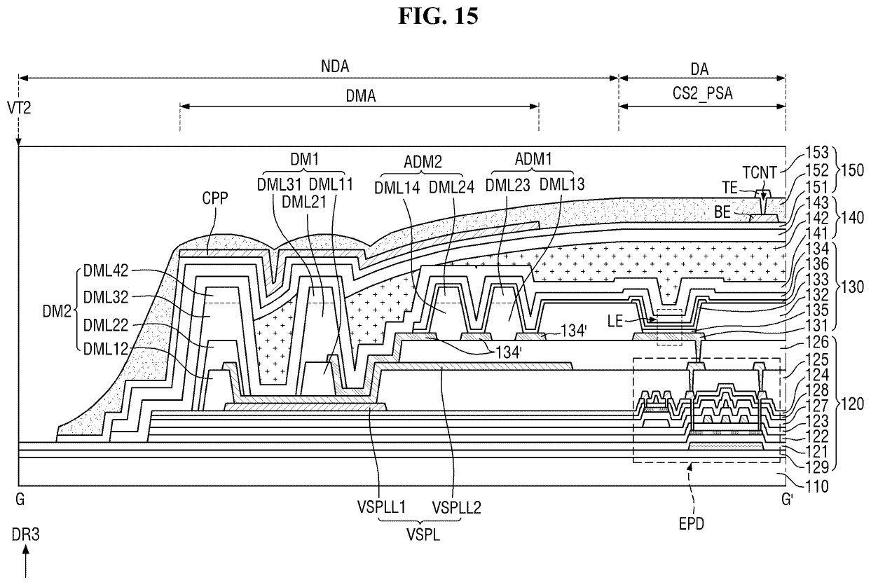

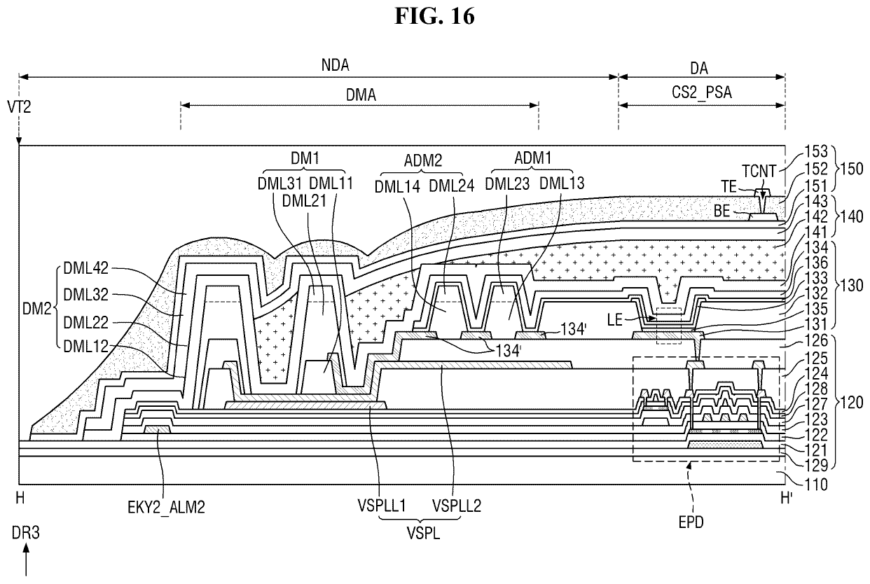

FIG. 15 is a cross-sectional view taken along line G-G′ of FIG. 14. FIG. 16 is a cross-sectional view taken along line H-H′ of FIG. 14.

As illustrated in FIG. 15, according to embodiments, the peripheral display area CS2_PSA of the display area DA includes emission areas EA, like the front display area FSA. Accordingly, the element layer 130 may include light emitting elements LE disposed in the emission areas EA of the peripheral display area CS2_PSA, and the circuit layer 120 may include emission pixel drivers EPD electrically connected to the light emitting elements LE of the peripheral display area CS2_PSA.

According to embodiments, each of one or more dam portions disposed in the dam area DMA of the non-display area NDA may include two or more dam layers DML11, DML21, and DML31; DML12, DML22, DML32, and DML42; DML13 and DML23; or DML14 and DML24.

Each of the two or more dam layers DML11, DML21, and DML31; DML12, DML22, DML32, and DML42; DML13 and DML23; or DML14 and DML24 may be disposed at the same layer as one of the first planarization layer 125, the second planarization layer 126, the pixel defining layer 132, and the spacer layer 132′ (see FIGS. 11 and 13).

In an embodiment, for example, one or more dam portions disposed in the dam area DMA may include a first dam portion DM1 surrounding the display area DA and a second dam portion DM2 surrounding the first dam portion DM1.

The first dam portion DM1 may include a first dam layer DML11 disposed at a same layer as the second planarization layer 126, a second dam layer DML21 disposed at a same layer as the pixel defining layer 132, and a third dam layer DML31 disposed at a same layer as the spacer layer 132′. Here, layers disposed at a same layer as each other may correspond to patterned portions of a same layer or layers formed during a same process using a same material.

The second dam portion DM2 may include a first dam layer DML12 disposed at the first planarization layer 125, a second dam layer DML22 disposed at a same layer as the second planarization layer 126, a third dam layer DML32 disposed at a same layer as the pixel defining layer 132, and a fourth dam layer DML42 disposed at a same layer as the spacer layer 132′.

One or more dam portions disposed in the dam area DMA may further include one or more auxiliary dam portion ADM1 and ADM2 arranged between the display area DA and the first dam portion DM1 and surrounding the display area DA.

One or more auxiliary dam portion ADM1 and ADM2 may include first dam layers DML13 and DML14 disposed on the second planarization layer 126 and second dam layers DML23 and DML24 disposed on the first dam layers DML13 and DML14, respectively.

As an example, one or more auxiliary dam portion may include a first auxiliary dam portion ADM1 disposed adjacent to the display area DA and a second auxiliary dam portion ADM2 disposed between the first auxiliary dam portion ADM1 and the first dam portion DM1.

The first dam layers DML13 and DML14 of the first auxiliary dam portion ADM1 and the second auxiliary dam portion ADM2 may be disposed at a same layer as the pixel defining layer 132.

The second dam layers DML23 and DML24 of the first auxiliary dam portion ADM1 and the second auxiliary dam portion ADM2 may be disposed at a same layer as the spacer layer 132′.

According to embodiments, the circuit layer 120 may include the power supply line VSPL overlapping the dam area DMA.

A portion of the power supply line VSPL overlapping the dam area DMA may include a first line layer VSPLL1 disposed at a same layer as the first source/drain conductive layer disposed on the interlayer insulating layer 124 and a second line layer VSPLL2 disposed at a same layer as the second source/drain conductive layer disposed on the first planarization layer 125.

The first planarization layer 125 and the second planarization layer 126 are removed in an area between the first dam portion DM1 and the second dam portion DM2 spaced apart from each other in the dam area DMA, and accordingly, the second line layer VSPLL2 may be in direct contact with the first line layer VSPLL1. Accordingly, the second line layer VSPLL2 may be electrically connected to the first line layer VSPLL1.

According to embodiments, the circuit layer 120 may further include cathode extension lines 134′ disposed in the non-display area NDA.

The cathode extension line 134′ may be provided at a same layer as the anode electrode 131. That is, the cathode extension line 134′ may be disposed on the second planarization layer 126.

When the power supply line VSPL transfers the second power ELVSS (see FIGS. 10 and 12), the cathode extension line 134′ may extend from the edge of the display area DA to the dam area DMA.

The pixel defining layer 132 and the spacer layer 132′ are removed in an area between the first dam DM1 and the second auxiliary dam ADM2 spaced apart from each other, and accordingly, the cathode extension line 134′ may be in direct contact with the second line layer VSPLL2 of the power supply line VSPL. Accordingly, the cathode extension line 134′ may be electrically connected to the power supply line VSPL.

According to embodiments, the capping portion CPP disposed on the touch buffer layer 151 may overlap all of one or more dam portions DM1, DM2, ADM1, and ADM2.

Accordingly, even though portions of one or more dam portions DM1, DM2, ADM1, and ADM2 are not covered with the touch interlayer insulating layer 152 including the organic insulating material, the portions of one or more dam portions DM1, DM2, ADM1, and ADM2 not covered with the touch interlayer insulating layer 152 may be protected from the etching process for disposing the second touch conductive layer TE and RE by the capping portion CPP.

According to embodiments, the first planarization layer 125, the second planarization layer 126, the pixel defining layer 132, the spacer layer 132′, the touch interlayer insulating layer 152, and the touch planarization layer 153 that include an organic insulating material may be spaced apart from the edge of the substrate 110 such that penetration of oxygen or moisture by the organic insulating material from the edge of the substrate 110 may be effectively prevented.

Accordingly, as illustrated in FIG. 16, according to an embodiment, the alignment marks EKY2_ALM2; ALMS (see FIG. 3) may be defined by a conductive layer covered with the interlayer insulating layer 124 including an inorganic insulating material.

That is, according to an embodiment, the alignment marks EKY2_ALM2; ALMS (see FIG. 3) may be defined by embossed patterns disposed at a same layer as one of the first gate conductive layer G1 and G6 (see FIG. 11) disposed on the first gate insulating layer 122 and the second gate conductive layer CAE (see FIG. 11) disposed on the second gate insulating layer 123.

Alternatively, according to an embodiment, the alignment marks EKY2_ALM2; ALMS (see FIG. 3) may be defined by embossed patterns disposed at a same layer as one of the first gate conductive layer G1, G2, and G6 (see FIG. 13) disposed on the first gate insulating layer 122, the second gate conductive layer CAE and LB2 (see FIG. 13) disposed on the second gate insulating layer 123, and the third gate conductive layer G4 (see FIG. 13) disposed on the third gate insulating layer 128.

According to an embodiment, the alignment marks EKY2_ALM2; ALMS (see FIG. 3) may be disposed adjacent to the edge of the substrate 110 such that the alignment marks EKY2_ALM2; ALMS (see FIG. 3) may be effectively prevented from being hidden or covered by another conductive layer disposed on the interlayer insulating layer 124. That is, the alignment marks EKY2_ALM2; ALMS (see FIG. 3) may be disposed between the dam area DMA and the corner points VT2; VT1, VT2, VT3, and VT4 (see FIG. 3) of the main area MA.

According to an embodiment of FIG. 14, four alignment marks EKY2_ALM2; ALMS (see FIG. 3) are disposed in embossed patterns between the four corner points VT2; VT1, VT2, VT3, and VT4 (see FIG. 3) of the main area MA and the dam area DMA, respectively, and the alignment marks EKY2_ALM2; ALMS (see FIG. 3) include the first, second, and third keys EKY1, EKY2, and EKY3 respectively having the ribbon pattern, the W pattern, and the cross pattern, and accordingly, there may be a limitation in reducing a width of the non-display area NDA due to the disposition of the alignment marks ALMS (see FIG. 3).

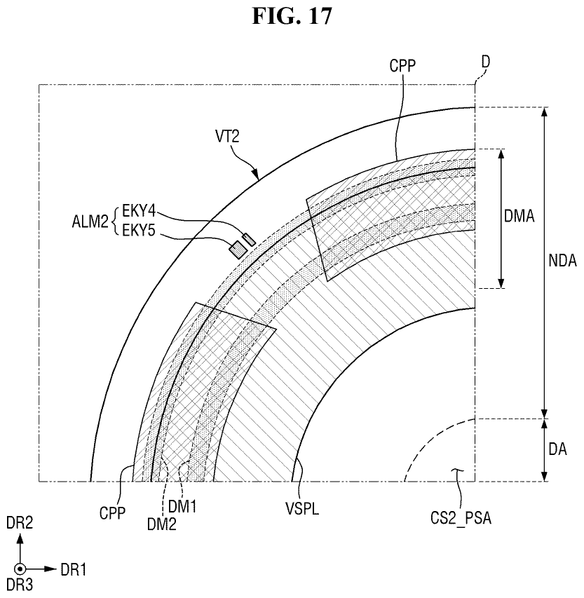

FIG. 17 is a plan view illustrating portion D of FIG. 3 according to an embodiment. A display device 10 according to an embodiment illustrated in FIG. 17 is substantially the same as the display device according to an embodiment illustrated in FIGS. 14 to 16 except that each of the alignment marks ALM2; ALMS (see FIG. 3) includes a fourth key EKY4 and a fifth key EKY5 spaced apart from each other and having different rectangular patterns, instead of the first, second, and third keys EKY1, EKY2, and EKY3 respectively having the ribbon pattern, the W pattern, and the cross pattern, and any repetitive detailed description of the same or like elements as those described above with reference to FIGS. 14 to 16 will thus be omitted below.

In an embodiment, the rectangular pattern of the fourth key EKY4 and the rectangular pattern of the fifth key EKY5 may be arranged in parallel with each other.

In such an embodiment, a width of each of the alignment marks ALM2; ALMS (see FIG. 3) may be reduced, and thus, a width of the non-display area NDA may be reduced.

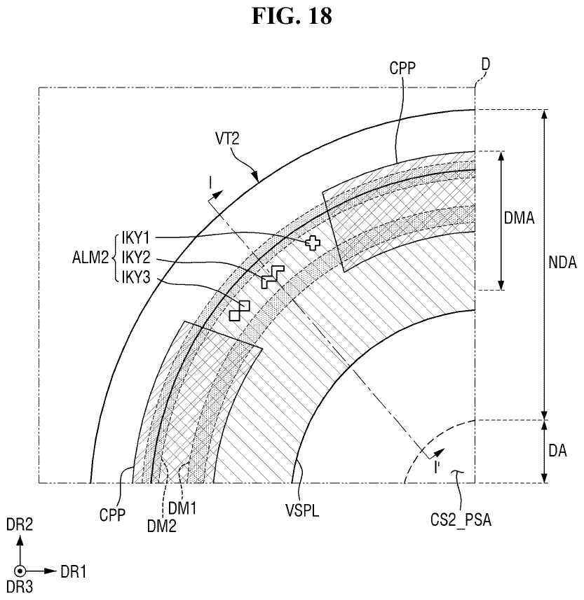

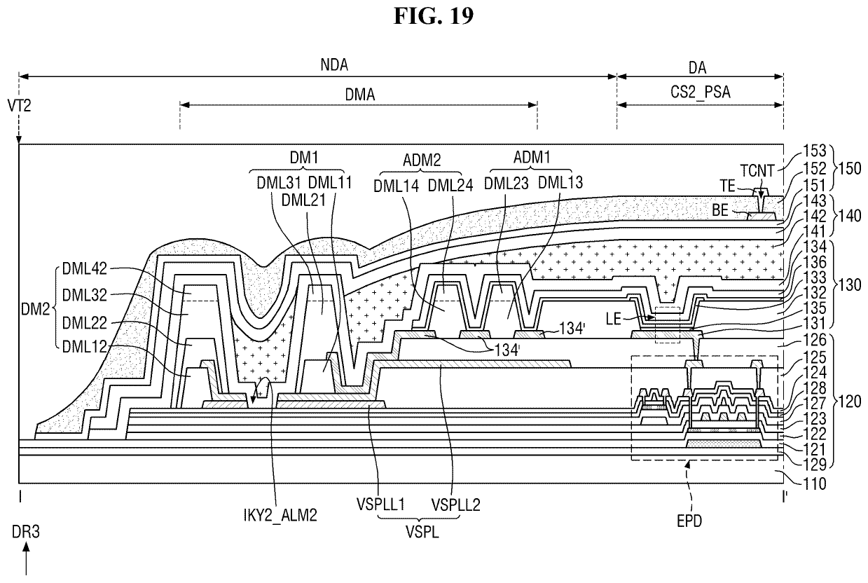

FIG. 18 is a plan view illustrating portion D of FIG. 3 according to an embodiment. FIG. 19 is a cross-sectional view taken along line I-I′ of FIG. 18.

A display device 10 according to an embodiment illustrated in FIGS. 18 and 19 is substantially the same as the display device according to an embodiment illustrated in FIGS. 14 to 16 except that the first, second, and third keys of each of the alignment marks ALM2; ALMS (see FIG. 3) are defined by engraved patterns IKY1, IKY2, and IKY3 defined or formed through the power supply line VSPL rather than the embossed patterns EKY1, EKY2, and EKY3, and any repetitive detailed description of the same or like elements as those described above with reference to FIGS. 14 to 16 will thus be omitted below.

As illustrated in FIG. 19, according to an embodiment, a portion of the power supply line VSPL overlapping the dam area DMA may include a first line layer VSPLL1 disposed at a same layer as the first source/drain conductive layer disposed on the interlayer insulating layer 124 and a second line layer VSPLL2 disposed at a same layer as the second source/drain conductive layer disposed on the first planarization layer 125.

In addition, in an area between the first dam portion DM1 and the second dam portion DM2 spaced apart from each other in the dam area DMA, the second line layer VSPLL2 may be in direct contact with the first line layer VSPLL1.

That is, a portion of the power supply line VSPL overlapping the area between the first dam portion DM1 and the second dam portion DM2 spaced apart from each other may include the first line layer VSPLL1 and the second line layer VSPLL2 that are sequentially stacked.

First, second, and third keys IKY1, IKY2, and IKY3 of each of the alignment marks IKY2_ALM2; ALMS (see FIG. 3) may be defined by engraved patterns defined or formed through the first line layer VSPLL1 and the second line layer VSPLL2 that are sequentially stacked.

In such an embodiment, as illustrated in FIG. 18, the alignment marks ALM2; ALMS (see FIG. 3) may be disposed in the area between the first dam portion DM1 and the second dam portion DM2 spaced apart from each other in the dam area DMA, and thus, an increase in width of the non-display area NDA due to the disposition of the alignment marks ALMS (see FIG. 3) may be effectively prevented.

According to embodiments illustrated in FIGS. 14 to 19, the capping portions CPP arranged in the dam area DMA may be disposed in an island shape in which they are spaced apart from the alignment marks ALMS (see FIG. 3). In such embodiments, an influence of static electricity introduced into the edge of the substrate 110 on the capping portions CPP may increase.

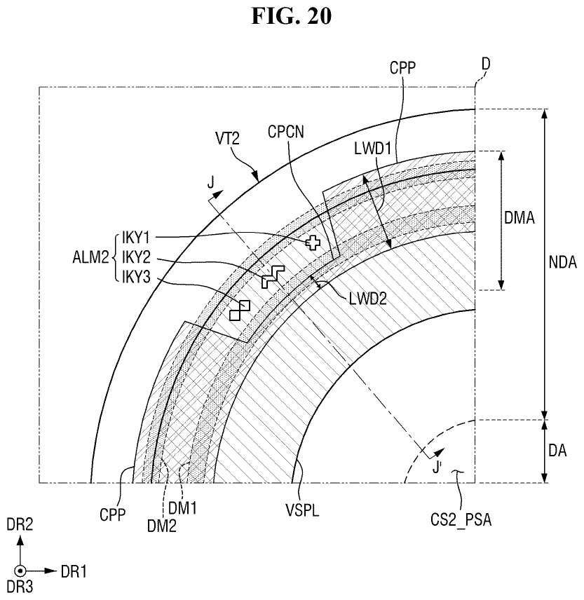

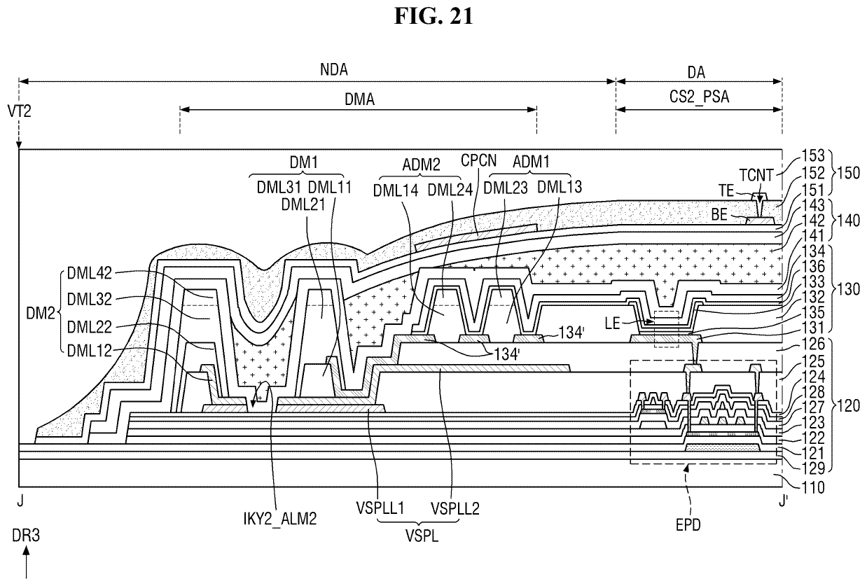

FIG. 20 is a plan view illustrating portion D of FIG. 3 according to an embodiment. FIG. 21 is a cross-sectional view taken along line J-J′ of FIG. 20.

A display device 10 according to an embodiment illustrated in FIGS. 20 and 21 is substantially the same as the display devices according to embodiments illustrated in FIGS. 14 to 19 except that the display device 10 further includes capping connection portions CPCN connecting the capping portions CPP to each other, having a smaller width than the capping portions CPP, and spaced apart from the alignment marks ALMS (see FIG. 3), and any repetitive detailed description of the same or like elements as those described above with reference to FIGS. 14 to 19 will thus be omitted below.

In an embodiment, as illustrated in FIG. 20, the capping portions CPP may be spaced apart from the alignment marks ALM2; ALMS (see FIG. 3) along an extension direction of the dam area DMA.

Each of the capping portions CPP may be disposed to have a first line width LWD1 in a direction perpendicular to the extension direction of the dam area DMA.

The capping connection portions CPCN may be disposed in parallel with the alignment marks ALM2; ALMS (see FIG. 3) in the extension direction of the dam area DMA, and may connect neighboring capping portions CPP of the capping portions CPP to each other.

The capping connection portions CPCN may be spaced apart from the alignment marks ALM2; ALMS (see FIG. 3) in the direction perpendicular to the extension direction of the dam area DMA, and may be disposed to have a second line width LWD2 smaller than the first line width LWD1.

In such an embodiment where capping connection portions CPCN is provided, the capping portions CPP may have a closed curve shape rather than the island shape, and thus, an influence of static electricity may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel which emits light to display an image,
wherein the display panel includes:
a substrate;
a circuit layer disposed on the substrate; and
an element layer disposed on the circuit layer,
wherein a main area of the substrate includes a display area where emission areas are arranged and a non-display area disposed around the display area,
wherein the display area includes a front display area and a peripheral display area disposed around the front display area and having a curved shape,
wherein the element layer includes light emitting elements respectively disposed in the emission areas,
wherein the circuit layer includes:
emission pixel drivers electrically connected to the light emitting elements, respectively; and
an alignment mark disposed in the non-display area,
wherein an edge of the main area includes four corner points where sides of the main area extending in different directions are connected to each other, and
wherein the alignment mark is disposed adjacent to a corresponding corner point of the four corner points.

2. The display device of claim 1, wherein the front display area includes a first side and a second side which extend in a first direction and oppose each other, and a third side and a fourth side which extend in a second direction crossing the first direction and oppose each other,
wherein the peripheral display area includes:
a first side area, a second side area, a third side area, and a fourth side area in contact with the first side, the second side, the third side, and the fourth side of the front display area, respectively;
a first corner area in contact with a vertex where the first side and the third side are connected to each other and disposed between the first side area and the third side area;
a second corner area in contact with a vertex where the second side and the third side are connected to each other and disposed between the second side area and the third side area;
a third corner area in contact with a vertex where the second side and the fourth side are connected to each other and disposed between the second side area and the fourth side area; and
a fourth corner area in contact with a vertex where the first side and the fourth side are connected to each other and disposed between the first side area and the fourth side area, and
wherein the alignment mark includes at least one selected from:
a first alignment mark disposed adjacent to the first corner area;
a second alignment mark disposed adjacent to the second corner area;
a third alignment mark disposed adjacent to the third corner area; and
a fourth alignment mark disposed adjacent to the fourth corner area.

3. The display device of claim 1, wherein the display panel further includes:
a sealing layer disposed on the element layer;
a touch sensor layer disposed on the sealing layer; and
one or more dam portions arranged in a dam area of the non-display area surrounding the display area and spaced apart from the display area,
wherein the circuit layer includes:
an interlayer insulating layer disposed on the substrate;
a first source/drain conductive layer disposed on the interlayer insulating layer;
a first planarization layer covering the first source/drain conductive layer;
a second source/drain conductive layer disposed on the first planarization layer, and
a second planarization layer covering the second source/drain conductive layer,
wherein the element layer includes:
a pixel defining layer disposed on the circuit layer and overlapping an area between the emission areas spaced apart from each other; and
a spacer layer disposed on portions of the pixel defining layer,
wherein the touch sensor layer includes:
a touch buffer layer disposed on the sealing layer;
a first touch conductive layer disposed on the touch buffer layer;
a touch interlayer insulating layer covering the first touch conductive layer;
a second touch conductive layer disposed on the touch interlayer insulating layer; and
a touch planarization layer covering the second touch conductive layer,
wherein the one or more dam portions include two or more dam layers, and
wherein each of the two or more dam layers is disposed at the same layer as a corresponding one of the first planarization layer, the second planarization layer, the pixel defining layer, and the spacer layer.

4. The display device of claim 3, wherein the touch interlayer insulating layer includes an organic insulating material, and
wherein the display device further comprises capping portions disposed at a same layer as the first touch conductive layer, overlapping the dam area, and spaced apart from the alignment mark in a plan view.

5. The display device of claim 4, further comprising capping connection portions connect neighboring capping portions of the capping portions to each other, disposed to have a smaller width than the capping portions, and spaced apart from the alignment mark.

6. The display device of claim 3, wherein the circuit layer further includes a power supply line disposed in the non-display area, wherein the power supply line transfers a power for driving the light emitting elements,
wherein a portion of the power supply line overlapping the dam area includes a first line layer disposed at a same layer as the first source/drain conductive layer and a second line layer disposed at a same layer as the second source/drain conductive layer and in contact with the first line layer, and
wherein the alignment mark is defined by an engraved pattern defined through the first line layer and the second line layer which are sequentially stacked.

7. The display device of claim 3, wherein the circuit layer further includes:
a first semiconductor layer disposed on the substrate;
a first gate insulating layer covering the first semiconductor layer;
a first gate conductive layer disposed on the first gate insulating layer;
a second gate insulating layer covering the first gate conductive layer; and
a second gate conductive layer disposed on the second gate insulating layer.

8. The display device of claim 7, wherein the interlayer insulating layer covers the second gate conductive layer, and
wherein the alignment mark is defined by an embossed pattern disposed at a same layer as one of the first gate conductive layer and the second gate conductive layer.

9. The display device of claim 7, wherein the circuit layer further includes:
an auxiliary interlayer insulating layer covering the second gate conductive layer;
a second semiconductor layer disposed on the auxiliary interlayer insulating layer;
a third gate insulating layer covering the second semiconductor layer; and
a third gate conductive layer disposed on the third gate insulating layer and covered with the interlayer insulating layer, and
the alignment mark is defined by an embossed pattern disposed at a same layer as one of the first gate conductive layer, the second gate conductive layer, and the third gate conductive layer.

10. The display device of claim 3, further comprising:
a bracket supporting the display panel; and
a cover window disposed on the display panel and coupled to the bracket,
wherein the cover window is provided with alignment holes defined therein to correspond to the alignment mark, and
the peripheral display area has a shape curved toward the bracket.

11. The display device of claim 3, wherein the alignment mark includes two or more keys spaced apart from each other.

12. A display device comprising:
a display panel which emits light to display an image;
a bracket supporting the display panel; and
a cover window disposed on the display panel and coupled to the bracket,
wherein the display panel includes:
a substrate;
a circuit layer disposed on the substrate; and
an element layer disposed on the circuit layer,
wherein a main area of the substrate includes a display area where emission areas are arranged and a non-display area disposed around the display area,
wherein the display area includes a front display area and a peripheral display area disposed around the front display area and having a shape curved toward the bracket,
wherein the circuit layer includes an alignment mark disposed in the non-display area,
wherein an edge of the main area includes four corner points where sides of the main area extending in different directions are connected to each other,
wherein the alignment mark is disposed adjacent to a corner point of the four corner points, and
wherein the cover window is provided with an alignment hole defined therein to correspond to the alignment mark.

13. The display device of claim 12, wherein the element layer includes light emitting elements respectively disposed in the emission areas, and
wherein the circuit layer further includes:
emission pixel drivers electrically connected to the light emitting elements, respectively; and
a power supply line disposed in the non-display area, wherein the power supply line transfers a power for driving the light emitting elements.

14. The display device of claim 13, wherein the display panel further includes:
a sealing layer disposed on the element layer;
a touch sensor layer disposed on the sealing layer; and
one or more dam portions arranged in a dam area of the non-display area surrounding the display area and spaced apart from the display area,
wherein the circuit layer includes:
a first semiconductor layer disposed on the substrate;
a first gate insulating layer covering the first semiconductor layer;
a first gate conductive layer disposed on the first gate insulating layer;
a second gate insulating layer covering the first gate conductive layer; and
a second gate conductive layer disposed on the second gate insulating layer;
an interlayer insulating layer disposed on the second gate conductive layer;
a first source/drain conductive layer disposed on the interlayer insulating layer;
a first planarization layer covering the first source/drain conductive layer;
a second source/drain conductive layer disposed on the first planarization layer, and
a second planarization layer covering the second source/drain conductive layer,
wherein the element layer includes:
a pixel defining layer disposed on the circuit layer and overlapping an area between the emission areas spaced apart from each other; and
a spacer layer disposed on portions of the pixel defining layer,
wherein the touch sensor layer includes:
a touch buffer layer disposed on the sealing layer;
a first touch conductive layer disposed on the touch buffer layer;
a touch interlayer insulating layer covering the first touch conductive layer;
a second touch conductive layer disposed on the touch interlayer insulating layer; and
a touch planarization layer covering the second touch conductive layer,
wherein the one or more dam portions include two or more dam layers, and
wherein each of the two or more dam layers is disposed at the same layer as a corresponding one of the first planarization layer, the second planarization layer, the pixel defining layer, and the spacer layer.

15. The display device of claim 14, wherein the touch interlayer insulating layer includes an organic insulating material, and
wherein the display device further comprises capping portions disposed at a same layer as the first touch conductive layer, overlapping the dam area, and spaced apart from the alignment mark in a plan view.

16. The display device of claim 15, further comprising capping connection portions connect neighboring capping portions of the capping portions to each other, disposed to have a smaller width than the capping portions, and spaced apart from the alignment mark.

17. The display device of claim 14, wherein a portion of the power supply line overlapping the dam area includes a first line layer disposed at a same layer as the first source/drain conductive layer and a second line layer disposed at a same layer as the second source/drain conductive layer and in contact with the first line layer, and
wherein the alignment mark is defined by an engraved pattern defined through the first line layer and the second line layer which are sequentially stacked.

18. The display device of claim 14, wherein the interlayer insulating layer covers the second gate conductive layer, and
wherein the alignment mark is defined by an embossed pattern disposed in a same layer as one of the first gate conductive layer and the second gate conductive layer.

19. The display device of claim 14, wherein the circuit layer further includes:
an auxiliary interlayer insulating layer covering the second gate conductive layer;
a second semiconductor layer disposed on the auxiliary interlayer insulating layer;
a third gate insulating layer covering the second semiconductor layer; and
a third gate conductive layer disposed on the third gate insulating layer and covered with the interlayer insulating layer, and
wherein the alignment mark is defined by an embossed pattern disposed in a same layer as one of the first gate conductive layer, the second gate conductive layer, and the third gate conductive layer.

20. The display device of claim 12, wherein the alignment mark includes two or more keys having different shapes from each other and spaced apart from each other.
